(19) United States
(12) Patent Application Publication
(10) Pub. No.: US 2025/0085330 A1
(43) Pub. Date: Mar. 13, 2025

(54) CONTROL CIRCUIT AND SEMICONDUCTOR MODULE

(71) Applicant: FUJI ELECTRIC CO., LTD., Kawasaki-shi (JP)

(72) Inventor: Tatsuya OYOBIKI, Matsumoto-city (JP)

(73) Assignee: FUJI ELECTRIC CO., LTD., Kawasaki-shi (JP)

(21) Appl. No.: 18/781,484

(22) Filed: Jul. 23, 2024

(30) Foreign Application Priority Data
Sep. 13, 2023 (JP) 2023-148325

(51) Int. Cl. G01R 31/26

(52) U.S. Cl. CPC G01R 31/2642

(57) ABSTRACT

An object of the present invention is to provide a control circuit and a semiconductor module that can control detection of a defective state due to the life of an optical coupler. A control circuit includes: a photo coupler defect detecting circuit configured to detect a defective state including deterioration and abnormality of a photo coupler; and a warning output circuit configured to notify that the defective state of the photo coupler is detected by the photo coupler defect detecting circuit.

### CROSS-REFERENCE TO RELATED APPLICATION

This application claims benefit of priority under 35 USC 119 based on Japanese Patent Application No. 2023-148325, filed on Sep. 13, 2023, the entire contents of which are incorporated by reference herein.

### TECHNICAL FIELD

The present invention relates to a control circuit and a semiconductor module for controlling detection of the defective state of an optical coupler.

### BACKGROUND ART

A semiconductor module used as a three-phase alternating current inverter receives a signal via a photo coupler provided in a control substrate. The photo coupler plays a role to electrically insulate a controlled source and a control device (for example, a microcomputer) provided on the control substrate from the semiconductor module. A technology using such a photo coupler is disclosed in PTLS 1 to 3.

PTL 1 discloses a technology in which “a gate-drive PMW signal generated from a gate signal generator is transmitted to a gate driver via a photo coupler in an insulating manner and is also input into a life prediction device, and current conversion efficiency of the photo coupler is estimated by the life prediction device based on the inclination of the fall of an output signal from the photo coupler so as to predict the time when the photo coupler reaches its life limit.”

PTL 2 discloses a technology in which “a comparator for comparing an output voltage from a photo coupler with a preset threshold, and a deterioration determination unit for determining whether or not the photo coupler deteriorates based on the output signal from the comparator and a drive signal from the photo coupler are provided, and when the drive signal from the photo coupler is active and the output voltage from the photo coupler is lower than the threshold, the deterioration determination unit determines that the photo coupler deteriorates.”

PTL 3 discloses such a technology that: “a photo coupler communication system includes a photo coupler, a current adjusting unit, an output signal generation unit configured to generate an output signal corresponding to a secondary current of the photo coupler, and a data processing control unit configured to control the current adjusting unit to adjust a primary current of the photo coupler and receive the output signal; and in a normal operation mode in which a signal is transmitted from one device to another device by the photo coupler, the data processing control unit changes the primary current of the photo coupler between a first current value and a second current value smaller than that, and in a verification mode, the data processing control unit sets the primary current of the photo coupler to the second current value and determines deterioration of the photo coupler based on an output signal at this time.”

### CITATION LIST

### Patent Literatures

PTL 1: JP 2008-268002 A
PTL 2: JP 2009-71928 A
PTL 3: JP 2015-211246 A

### SUMMARY OF INVENTION

### Technical Problem

A photo coupler includes a light-emitting element and a light-receiving element. The light-emitting element (for example, a light-emitting diode (LED)) has a life span that deteriorates by aging. It is known that the intensity of light emitted from the light-emitting element decreases due to long-term deterioration. Even when a current of the same amount as that of the current at the beginning of packaging flows through the light-emitting element, the intensity of light emitted from the light-emitting element decreases due to long-term deterioration and becomes lower than that at the beginning of packaging. As a result, the intensity of light received by the light-receiving element decreases. This causes poor transmission of a signal due to the long-term deterioration of the light-emitting element in the photo coupler. On this account, it is necessary that the photo coupler used for signal transmission between devices be replaced in five to six years in general.

However, the life of the light-emitting element such as an LED provided in the photo coupler can vary depending on an operating condition or an environmental temperature even when the light-emitting element is used for the same product. Accordingly, there is such a problem that it is difficult to uniquely determine a timing to replace the photo coupler. Further, this problem is not limited to the photo coupler, and components externally attached to a semiconductor module also have a problem that it is difficult to uniquely determine their replacement timings along with long-term deterioration.

An object of the present invention is to provide a control circuit and a semiconductor module each of which can control detection of a defective state caused due to the life of an optical coupler.

### Solution to Problem

In order to achieve the above object, a control circuit according to one aspect of the present invention includes: a detecting unit configured to detect a defective state including deterioration and abnormality of an optical coupler; and a notifier configured to notify that the defective state is detected by the detecting unit.

Further, in order to achieve the above object, a semiconductor module according to one aspect of the present invention includes: the control circuit according to the above aspect; and a semiconductor switching element controlled based on a control signal.

### Advantageous Effects of Invention

With one aspect of the present invention, it is possible to control detection of a defective state caused due to the life of an optical coupler.

### BRIEF DESCRIPTION OF DRAWINGS

FIG. 1 is a view illustrating an example of the schematic configuration of a control circuit and a semiconductor module according to a first embodiment of the present invention;

FIG. 2 is a circuit diagram illustrating an example of the schematic configuration of the control circuit according to the first embodiment of the present invention;

FIG. 3 is a view schematically illustrating an example of the operation of a photo coupler connected to the control circuit and the semiconductor module according to the first embodiment of the present invention;

FIG. 4 is a timing chart illustrating an example of the operation of the control circuit according to the first embodiment of the present invention;

FIG. 5 is a view illustrating an example of the schematic configuration of a control circuit and a semiconductor module according to a second embodiment of the present invention;

FIG. 6 is a circuit diagram illustrating an example of the schematic configuration of the control circuit according to the second embodiment of the present invention; and

FIG. 7 is a timing chart illustrating an example of the operation of the control circuit according to the second embodiment of the present invention.

### DESCRIPTION OF EMBODIMENTS

Embodiments of the present invention describe a device or a method to embody the technical idea of the present invention, and the technical idea of the present invention does not specify the material, shape, structure, arrangement, and the like of component parts to those described below. Various changes can be added to the technical idea of the present invention within a technical scope defined by claims described in Claims.

### First Embodiment

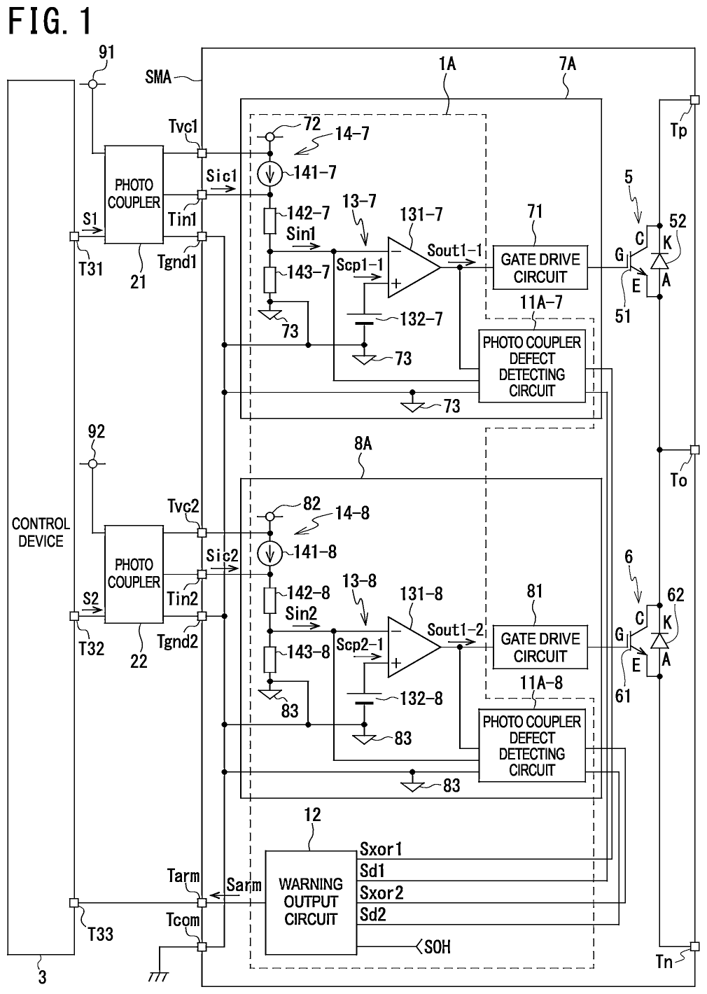

A control circuit and a semiconductor module according to a first embodiment of the present invention will be described with reference to FIGS. 1 to 4. The present embodiment and a second embodiment described later will be described with reference to, as a semiconductor module, an intelligent power module (IPM) collectively including, as one package, an insulated gate bipolar transistor (IGBT) for power conversion, a freewheeling diode, and a drive-protection function integrated circuit (IC) for driving and protecting the IGBT. However, the semiconductor module in each embodiment of the present invention is not limited to the IPM and is also applicable to a drive-protection function IC that is not integrated with a power semiconductor element such as an IGBT as one package.

### [Configuration of Semiconductor Module]

The schematic configuration of a semiconductor module SMA according to the present embodiment will be described with reference to FIG. 1. The semiconductor module SMA has a configuration to exercise a function as an inverter for converting a direct-current power into a single-phase alternating-current power.

As illustrated in FIG. 1, the semiconductor module SMA includes a control circuit 1A according to the present embodiment. Further, the semiconductor module SMA includes a high-side power supply terminal Tvc1, a high-side input terminal Tin1, a high-side ground terminal Tgnd1, a low-side power supply terminal Tvc2, a low-side input terminal Tin2, and a low-side ground terminal Tgnd2. Further, the semiconductor module SMA includes an IGBT 51 (an example of a semiconductor switching element) controlled based on a control signal Sic1, and an IGBT 61 (an example of a semiconductor switching element) controlled based on a control signal Sic2. The control signal Sic1 is input from a photo coupler 21 (an example of an optical coupler) via the high-side input terminal Tin1. The control signal Sic2 is input from a photo coupler 22 (an example of an optical coupler) via the low-side input terminal Tin2.

The semiconductor module SMA includes a high-side control integrated circuit 7A configured to control the IGBT 51. Hereinafter, the “high-side control integrated circuit” is referred to as a “high-side control IC.” The high-side control IC 7A has a signal generating circuit 14-7 configured to generate a first input signal Sin1 based on the control signal Sic1 input via the high-side input terminal Tin1, a first determination circuit 13-7 (an example of a first determination unit) configured to determine the signal level of the first input signal Sin1, a photo coupler defect detecting circuit 11A-7 (an example of a detecting unit) configured to detect a defective state including deterioration and abnormality of the photo coupler 21, and a gate drive circuit 71 configured to drive the IGBT 51.

The semiconductor module SMA includes a low-side control integrated circuit 8A configured to control the IGBT 61. The “low-side control integrated circuit” is hereinafter referred to as a “low-side control IC.” The low-side control IC 8A has a signal generating circuit 14-8 configured to generate a first input signal Sin2 based on the control signal Sic2 input via the low-side input terminal Tin2, a first determination circuit 13-8 (an example of the first determination unit) configured to determine the signal level of the first input signal Sin2, a photo coupler defect detecting circuit 11A-8 (an example of the detecting unit) configured to detect a defective state including deterioration and abnormality of the photo coupler 22, and a gate drive circuit 81 configured to drive the IGBT 61. Although details will be described later, the signal generating circuit 14-7, the first determination circuit 13-7, and the photo coupler defect detecting circuit 11A-7 provided in the high-side control IC 7A, and the signal generating circuit 14-8, the first determination circuit 13-8, and the photo coupler defect detecting circuit 11A-8 provided in the low-side control IC 8A are some of constituents constituting the control circuit 1A according to the present embodiment.

The semiconductor module SMA includes a freewheeling diode 52 connected in reverse-parallel to the IGBT 51. A semiconductor element 5 is constituted by the IGBT 51 and the freewheeling diode 52. A cathode K of the freewheeling diode 52 is connected to a collector C of the IGBT 51, and an anode A of the freewheeling diode 52 is connected to an emitter E of the IGBT 51. A gate G of the IGBT 51 is connected to an output of the gate drive circuit 71.

The semiconductor module SMA includes a freewheeling diode 62 connected in reverse-parallel to the IGBT 61. A semiconductor element 6 is constituted by the IGBT 61 and the freewheeling diode 62. A cathode K of the freewheeling diode 62 is connected to a collector C of the IGBT 61, and an anode A of the freewheeling diode 62 is connected to an emitter E of the IGBT 61. A gate G of the IGBT 61 is connected to an output of the gate drive circuit 81.

The semiconductor module SMA includes a positive-side power-input terminal Tp into which a positive-side direct-current voltage is input, a negative-side power-input terminal Tn into which a negative-side direct-current voltage is input, and an alternating-current voltage output terminal To into which alternating-current voltages obtained by converting the positive-side direct-current voltage and the negative-side direct-current voltage into the alternating-current voltages are output. The collector C of the IGBT 51 and the cathode K of the freewheeling diode 52 are connected to the positive-side power-input terminal Tp. The emitter E of the IGBT 61 and the anode A of the freewheeling diode 62 are connected to the negative-side power-input terminal Tn. The emitter E of the IGBT 51 and the anode A of the freewheeling diode 52 are connected to the collector C of the IGBT 61 and the cathode K of the freewheeling diode 62, and they are connected to the alternating-current voltage output terminal To.

The semiconductor module SMA includes a warning output circuit (an example of a notifier) 12 configured to notify that at least one of respective defective states of the photo couplers 21, 22 and respective overheating states of the IGBTS 51, 61 is detected. An output of the warning output circuit 12 is connected to an alarm terminal Tarm provided in the semiconductor module SMA. The warning output circuit 12 is configured to notify the defective state of the photo coupler 21, 22, and the like to outside the semiconductor module SMA via the alarm terminal Tarm.

The semiconductor module SMA includes a common reference potential terminal Tcom. The common reference potential terminal Tcom is a terminal connected to the ground, for example, and receiving an overall reference potential of the semiconductor module SMA. The high-side ground terminal Tgnd1 and the low-side ground terminal Tgnd2 are connected to the common reference potential terminal Tcom. Accordingly, the potential of the high-side ground terminal Tgnd1 and the potential of the low-side ground terminal Tgnd2 are the same potential and are a reference potential input from the common reference potential terminal Tcom.

As illustrated in FIG. 1, a control device 3 configured to control switching operations of the IGBTS 51, 61 is connected to the semiconductor module SMA. The control device 3 includes signal output terminals T31, T32 and a signal input terminal T33. The control device 3 is connected to the photo coupler 21 via the signal output terminal T31, connected to the photo coupler 22 via the signal output terminal T32, and connected to the semiconductor module SMA via the signal input terminal T33.

The control device 3 outputs an input signal S1 generated to control the switching operation of the IGBT 51 from the signal output terminal T31 to the photo coupler 21. The control device 3 outputs an input signal S2 generated to control the switching operation of the IGBT 61 from the signal output terminal T32 to the photo coupler 22.

The signal input terminal T33 is connected to the alarm terminal Tarm. An alarm signal Sarm output from the alarm terminal Tarm is input into the control device 3 via the signal input terminal T33.

The control device 3 controls the IGBT 51 and the IGBT 61 by the input signal S1 and the input signal S2 having phases reverse to each other by 180° such that the IGBT 61 is in an OFF state when the IGBT 51 is in an ON state, and the IGBT 61 is in the ON state when the IGBT 51 is in the OFF state. Due to the switching operations to repeatedly change the IGBTS 51, 61 between the ON state and the OFF state alternately at a predetermined timing, the positive-side direct-current voltage input from the positive-side power-input terminal Tp and the negative-side direct-current voltage input from the negative-side power-input terminal Tn are converted into alternating-current voltages, and the alternating-current voltages are output from the alternating-current voltage output terminal To. During the switching operation of the IGBT 51, 61, in a case where the alarm signal Sarm indicating that the defective state of the photo coupler 21, 22 or the overheating state of the IGBT 51, 61 is detected is input, the control device 3 outputs, to the photo coupler 21, 22, the input signal S1, S2 to stop the switching operation of the IGBT 51, 61 as needed and stops the inverter operation performed by the semiconductor module SMA.

### [Configuration of Control Circuit]

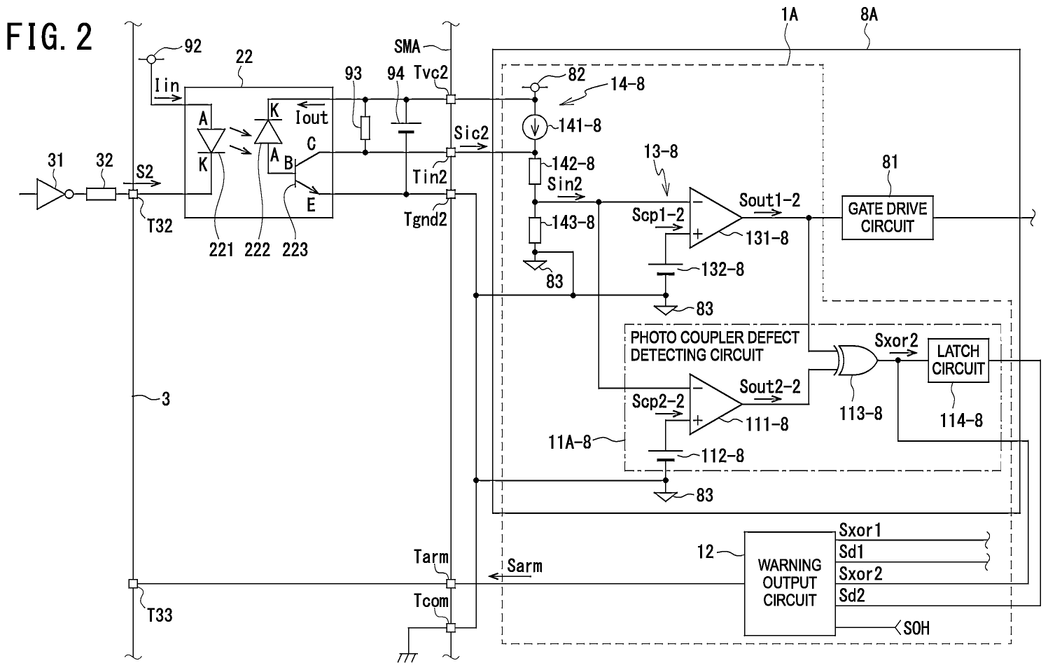

The schematic configuration of the control circuit 1A according to the present embodiment will be described with reference to FIG. 2 as well as FIG. 1. The signal generating circuit 14-7, the first determination circuit 13-7, and the photo coupler defect detecting circuit 11A-7 provided in the high-side control IC 7A as constituents of the control circuit 1A for detecting the defective state of the photo coupler 21 have the same configurations as the signal generating circuit 14-8, the first determination circuit 13-8, and the photo coupler defect detecting circuit 11A-8 provided in the low-side control IC 8A as constituents of the control circuit 1A for detecting the defective state of the photo coupler 22. On this account, in the description of the control circuit 1A, concrete configurations of the signal generating circuit 14-7, the first determination circuit 13-7, and the photo coupler defect detecting circuit 11A-7 are not described.

As illustrated in FIG. 2, the control circuit 1A includes the signal generating circuit 14-8 configured to generate the first input signal Sin2 based on the control signal Sic2 input via the low-side input terminal Tin2. The signal generating circuit 14-8 includes a constant current source 141-8, a resistance element 142-8, and a resistance element 143-8 serially connected between a power supply terminal 82 and a reference potential terminal 83. The power supply terminal 82 is a terminal configured to supply a power supply voltage to the low-side control IC 8A. The reference potential terminal 83 is a terminal configured to supply a reference potential to the low-side control IC 8A. A power-supply-side terminal of the constant current source 141-8 is connected to the power supply terminal 82, and an output terminal of the constant current source 141-8 is connected to one terminal of the resistance element 142-8. The other terminal of the resistance element 142-8 is connected to one terminal of the resistance element 143-8, and the other terminal of the resistance element 143-8 is connected to the reference potential terminal 83. The signal generating circuit 14-8 generates a signal having a voltage level of a voltage dropped in the resistance element 143-8 due to a current flowing from the constant current source 141-8 side, as the first input signal Sin2 based on the control signal Sic2.

The power-supply-side terminal of the constant current source 141-8 and the power supply terminal 82 are connected to the low-side power supply terminal Tvc2. The output terminal of the constant current source 141-8 and the one terminal of the resistance element 142-8 are connected to the low-side input terminal Tin2. The other terminal of the resistance element 143-8 and the reference potential terminal 83 are connected to the low-side ground terminal Tgnd2 and the common reference potential terminal Tcom. Accordingly, the reference potential of the low-side control IC 8A is the same potential as a reference potential input from the common reference potential terminal Tcom.

As illustrated in FIG. 2, the control circuit 1A includes the first determination circuit 13-8 configured to determine the signal level of the first input signal Sin2 based on the control signal Sic2. The first determination circuit 13-8 has a first comparator 131-8 configured to compare the signal level of the first input signal Sin2 with the signal level of a first compare signal Scp1-2 set at a predetermined signal level. The first comparator 131-8 is constituted by a hysteresis comparator, for example. The first determination circuit 13-8 has a compare signal generation section 132-8 configured to generate the first compare signal Scp1-2.

The signal level (a voltage level in the present embodiment) of the first compare signal Scp1-2 is set based on a designed value for the signal level (a voltage level in the present embodiment) of the first input signal Sin2 in a case where the photo coupler 22 has no deterioration. The signal level of the first compare signal Scp1-2 is set to a value (for example, 1.4 V) larger than the designed value for the signal level of the first input signal Sin2 in a period during which the IGBT 61 is controlled to the ON state.

The compare signal generation section 132-8 is constituted by a direct-current power supply, for example. A negative terminal of the compare signal generation section 132-8 is connected to the reference potential terminal 83. A positive terminal of the compare signal generation section 132-8 is connected to a noninverting input terminal (+) of the first comparator 131-8. An inverting input terminal (−) of the first comparator 131-8 is connected to the other terminal of the resistance element 142-8 and the one terminal of the resistance element 143-8. An output terminal of the first comparator 131-8 is connected to input sides of the photo coupler defect detecting circuit 11A-8 and the gate drive circuit 81.

Accordingly, the first comparator 131-8 compares the signal level of the first input signal Sin2 input from the signal generating circuit 14-8 with the signal level of the first compare signal Scp1-2 input from the compare signal generation section 132-8, in terms of voltage level. The first comparator 131-8 outputs a first output signal Sout1-2 based on a comparison result between the first input signal Sin2 and the first compare signal Scp1-2 to the photo coupler defect detecting circuit 11A-8 and the gate drive circuit 81. The gate drive circuit 81 generates a gate drive signal for driving the IGBT 61 (see FIG. 1) based on the first output signal Sout1-2 input from the first determination circuit 13-8.

As illustrated in FIG. 2, the control circuit 1A includes the photo coupler defect detecting circuit 11A-8 configured to detect a defective state including deterioration and abnormality of the photo coupler 22 (an example of an optical coupler). The photo coupler 22 is an external component connected to the low-side input terminal Tin2. The photo coupler defect detecting circuit 11A-8 has a second comparator 111-8, a compare signal generation section 112-8, an exclusive-OR gate (hereinafter referred to as an “XOR gate”) 113-8, and a latch circuit 114-8.

The second comparator 111-8 is constituted by a hysteresis comparator, for example. The second comparator 111-8 compares the signal level of the first input signal Sin2 with the signal level of a second compare signal Scp2-2 set at a signal level different from the first compare signal Scp1-2. The compare signal generation section 112-8 generates a second compare signal Scp2-2. The second compare signal Scp2-2 is set to a signal level (a voltage level in the present embodiment) lower than the first compare signal Scp1-2, so that the second comparator 111-8 can detect an increase in the signal level of the first input signal Sin2 earlier than the first comparator 131-8. Further, the signal level of the second compare signal Scp2-2 is set to be higher than the signal level of noise caused in a reference potential region or the control circuit 1A so that the second comparator 111-8 does not malfunction due to the noise. In a case where the first compare signal Scp1-2 is set to 1.4 V, for example, the second compare signal Scp2-2 is set to 1.2 V, for example.

The compare signal generation section 112-8 is constituted by a direct-current power supply, for example. A negative terminal of the compare signal generation section 112-8 is connected to the reference potential terminal 83. A positive terminal of the compare signal generation section 112-8 is connected to a noninverting input terminal (+) of the second comparator 111-8. An inverting input terminal (−) of the second comparator 111-8 is connected to the other terminal of the resistance element 142-8 and the one terminal of the resistance element 143-8. An output terminal of the second comparator 111-8 is connected to one input terminal of the XOR gate 113-8. Accordingly, the second comparator 111-8 compares the signal level of the first input signal Sin2 input from the signal generating circuit 14-8 with the signal level of the second compare signal Scp2-2 input from the compare signal generation section 112-8, in terms of voltage level. The second comparator 111-8 outputs a second output signal Sout2-2 based on a comparison result between the first input signal Sin2 and the second compare signal Scp2-2 to the XOR gate 113-8.

The other input terminal of the XOR gate 113-8 is connected to the output terminal of the first comparator 131-8, and an output terminal of the XOR gate 113-8 is connected to respective inputs of the latch circuit 114-8 and the warning output circuit 12. The XOR gate 113-8 performs an exclusive-OR operation on the signal level of the first output signal Sout1-2 input from the first determination circuit 13-8 and the signal level of the second output signal Sout2-2 input from the second comparator 111-8, in terms of voltage level. The XOR gate 113-8 outputs an operation result signal Sxor2 provided by the operation to the latch circuit 114-8.

An output terminal of the latch circuit 114-8 is connected to one of input terminals of the warning output circuit 12. The latch circuit 114-8 outputs, to the warning output circuit 12, a defect detecting signal Sd2 the signal level of which is at a low level, until the signal level of the operation result signal Sxor2 input from the XOR gate 113-8 reaches a high level, for example. In the meantime, the latch circuit 114-8 outputs, to the warning output circuit 12, the defect detecting signal Sd2 the signal level of which is at a high level, when the signal level of the operation result signal Sxor2 input from the XOR gate 113-8 reaches the high level, for example. After the latch circuit 114-8 outputs, to the warning output circuit 12, the defect detecting signal Sd2 the high signal of which is at the high level, even when the latch-circuit 114-8 receives the operation result signal Sxor2 the signal level of which is at the low level, the latch circuit 114-8 continues outputting, to the warning output circuit 12, the high-level defect detecting signal Sd2 until the signal level of the defect detecting signal Sd2 is reset.

Although detailed descriptions are omitted herein, as illustrated in FIG. 1, the signal generating circuit 14-7 has a configuration similar to that of the signal generating circuit 14-8 by reading the constant current source 141-8 as a constant current source 141-7, the resistance element 142-8 as a resistance element 142-7, the resistance element 143-8 as a resistance element 143-7, the power supply terminal 82 as a power supply terminal 72, and the reference potential terminal 83 as a reference potential terminal 73. The power supply terminal 72 is a terminal configured to supply a power supply voltage to the high-side control IC 7A. The reference potential terminal 73 is a terminal configured to supply a reference potential to the high-side control IC 7A. Note that a power-supply-side terminal of the constant current source 141-7 is connected to the power supply terminal 72 and the high-side power supply terminal Tvc1. The other terminal of the resistance element 143-7 is connected to the reference potential terminal 73 and the high-side ground terminal Tgnd1.

Further, the first determination circuit 13-7 has a configuration similar to that of the first determination circuit 13-8 by reading the first comparator 131-8 as a first comparator 131-7, and the compare signal generation section 132-8 as a compare signal generation section 132-7. Note that a negative terminal of the compare signal generation section 132-7 is connected to the reference potential terminal 73, and an output terminal of the first comparator 131-7 is connected to the gate drive circuit 71 and the photo coupler defect detecting circuit 11A-7.

The photo coupler defect detecting circuit 11A-7 has the same configuration as the photo coupler defect detecting circuit 11A-8. A noninverting input terminal of a second comparator (not illustrated) provided in the photo coupler defect detecting circuit 11A-7 is connected to a positive terminal of a compare signal generation section (not illustrated) provided in the photo coupler defect detecting circuit 11A-7. An inverting input terminal of the second comparator is connected to a connecting portion between the resistance element 142-7 and the resistance element 143-7 provided in the signal generating circuit 14-7. One input terminal of an XOR gate (not illustrated) provided in the photo coupler defect detecting circuit 11A-7 is connected to an output terminal of the second comparator. The other input terminal of the XOR gate is connected to the output terminal of the first comparator 131-7. A latch circuit (not illustrated) provided in the photo coupler defect detecting circuit 11A-7 generates a defect detecting signal Sd1 related to the defective state of the photo coupler 21 based on an operation result signal Sxor1 input from the XOR gate and outputs the generated defect detecting signal Sd1 to the warning output circuit 12.

Referring back to FIG. 2, the control circuit 1A includes the warning output circuit (an example of a notifier) 12 configured to notify that the defective state of the photo coupler 22 is detected by the photo coupler defect detecting circuit 11A-8. The photo coupler 22 corresponds to an example of an optical coupler. The warning output circuit 12 also notifies the defective state of the photo coupler 21 which defective state is detected by the photo coupler defect detecting circuit 11A-7 provided in the high-side control IC 7A. The photo coupler 21 also corresponds to an example of an optical coupler.

Although not illustrated herein, the semiconductor module SMA includes a detecting circuit configured to detect respective overheating states of the IGBTS 51, 61 (see FIG. 1). When the detecting circuit detects at least either one of the IGBTS 51, 61 being in the overheating state, the detecting circuit outputs an overheating detecting signal SOH to the warning output circuit 12. When the warning output circuit 12 receives the overheating detecting signal SOH from the detecting circuit, the warning output circuit 12 notifies that the IGBT 51, 61 is in the overheating state.

The warning output circuit 12 notifies the defective state of the photo coupler 21, 22 and the overheating state of the IGBT 51, 61, for example, by the signal level and the signal pattern of the alarm signal Sarm output from the alarm terminal Tarm. The warning output circuit 12 determines whether the photo coupler 21 is in the normal state or in the defective state, based on the signal level of the operation result signal Sxor1 input from the XOR gate provided in the photo coupler detect detecting circuit 11A-7 and the signal level of the defect detecting signal Sd1 input from the photo coupler defect detecting circuit 11A-7. The warning output circuit 12 also determines whether the photo coupler 22 is in the normal state or in the defective state, based on the signal level of the operation result signal Sxor2 input from the XOR gate 113-8 and the signal level of the defect detecting signal Sd2 input from the latch circuit 114-8.

In a case where the photo couplers 21, 22 are in the normal state (not in the defective state) and the IGBTS 51, 61 are not in the overheating state but in the normal state, the warning output circuit 12 maintains the alarm terminal Tarm at a high constant voltage level, for example. In the meantime, in a case where the defective state of the photo coupler 21, 22 or the overheating state of the IGBT 51, 61 is detected, the warning output circuit 12 changes the voltage level of the alarm terminal Tarm to the low level with a predetermined pattern so that the alarm terminal Tarm outputs the alarm signal Sarm the signal level of which is at the low level with the predetermined signal pattern, for example. Further, the warning output circuit 12 uses different signal patterns to change the signal level of the alarm signal Sarm to the low level for respective notification targets of the defective state of the photo coupler 21, the defective state of the photo coupler 22, the overheating state of the IGBT 51, and the overheating state of the IGBT 61. Hereby, the warning output circuit 12 can notify which one of the photo couplers 21, 22 and the IGBTS 51, 61 has a defect.

In addition, the warning output circuit 12 uses different signal patterns to change the signal level of the alarm signal Sarm to the low level depending on a deterioration level in terms of the defective states of the photo couplers 21, 22. This allows the control circuit 1A to separately notify the control device 3 of a deterioration alarm level at which the IGBT 51, 61 can be kept operating though the photo coupler 21, 22 deteriorates, and a deterioration level at which the IGBT 51, 61 needs to stop operating due to the deterioration of the photo coupler 21, 22.

As illustrated in FIG. 2, in the present embodiment, the photo coupler 22 has a light-emitting diode (LED) 221 as a light-emitting element, a photo diode 222 as a light-receiving element, and a transistor 223 constituted by a bipolar transistor. A cathode K of the light-emitting diode 221 is connected to the signal output terminal T32 of the control device 3, and an anode A of the light-emitting diode 221 is connected to a power supply terminal 92. The power supply terminal 92 is connected to a power supply circuit (not illustrated) provided in a control substrate (not illustrated) on which the control device 3 is provided. A power supply voltage at a predetermined voltage level is supplied to the power supply terminal 92 from the power supply circuit. A cathode K of the photo diode 222 is connected to the low-side power supply terminal Tvc2, and an anode A of the photo diode 222 is connected to a base B of the transistor 223. A collector C of the transistor 223 is connected to the low-side input terminal Tin2. An emitter E of the transistor 223 is connected to the low-side ground terminal Tgnd2. The photo diode 222 and the transistor 223 collaborate with each other to operate equivalent to a phototransistor.

As illustrated in FIG. 2, a constant voltage source 94 is connected between the low-side power supply terminal Tvc2 and the low-side ground terminal Tgnd2. A positive terminal of the constant voltage source 94 is connected to the low-side power supply terminal Tvc2, and a negative terminal of the constant voltage source 94 is connected to the low-side ground terminal Tgnd2. In view of this, the constant voltage source 94 serves as a power source for the low-side control IC 8A. The positive terminal of the constant voltage source 94 is also connected to the cathode K of the photo diode 222, and the negative terminal of the constant voltage source 94 is also connected to the emitter E of the transistor 223. A pull-up resistor 93 is connected between the cathode K of the photo diode 222 and the collector C of the transistor 223. The pull-up resistor 93 and the constant voltage source 94 are provided on the control substrate provided with the control device 3. Note that a stabilization capacitor for stabilizing a voltage level supplied from the constant voltage source 94 to the low-side power supply terminal Tvc2, or a by-pass capacitor for preventing noise from flowing into the semiconductor module SMA from the low-side power supply terminal Tvc2 may be provided between the low-side power supply terminal Tvc2 and the low-side ground terminal Tgnd2.

As illustrated in FIG. 2, the control device 3 has a resistance element 32 connected to the signal output terminal T32, and a logical negation gate (hereinafter referred to as an “NOT gate”) 31 connected to the resistance element 32. Although details are described later, the control device 3 outputs the input signal S1 to the photo coupler 22 via the resistance element 32 and the signal output terminal T32.

The photo coupler 21 (see FIG. 1) has the same configuration as the photo coupler 22, and a cathode of a light-emitting diode (not illustrated) provided in the photo coupler 21 is connected to the signal output terminal T31. A power supply terminal 91 is connected to an anode of the light-emitting diode provided in the photo coupler 21. The power supply terminal 91 is connected to a power supply circuit to which the power supply terminal 92 is connected.

Although not illustrated in FIG. 1 similarly to the photo coupler 22 side, a pull-up resistor and a constant voltage source corresponding to the pull-up resistor 93 and the constant voltage source 94 (see FIG. 2) are provided between the photo coupler 21 and the semiconductor module SMA. Note that a stabilization capacitor or a by-pass capacitor may be provided between the photo coupler 21 and the semiconductor module SMA.

Although not illustrated in FIG. 1, and an NOT gate and a resistance element corresponding to the NOT gate 31 and the resistance element 32 are connected to the signal output terminal T31 inside the control device 3.

### [Operation of Control Circuit]

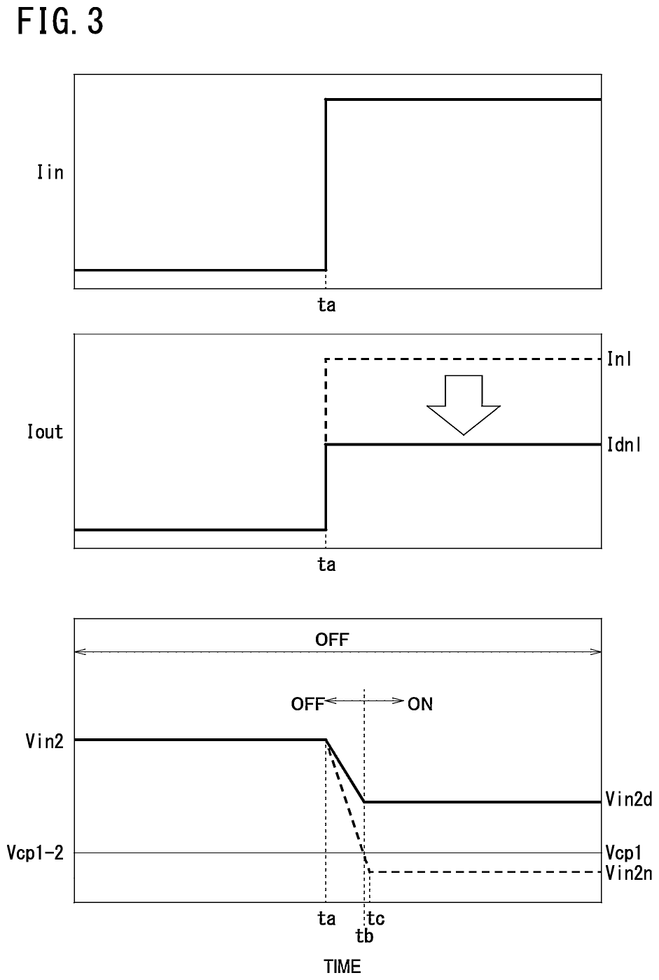

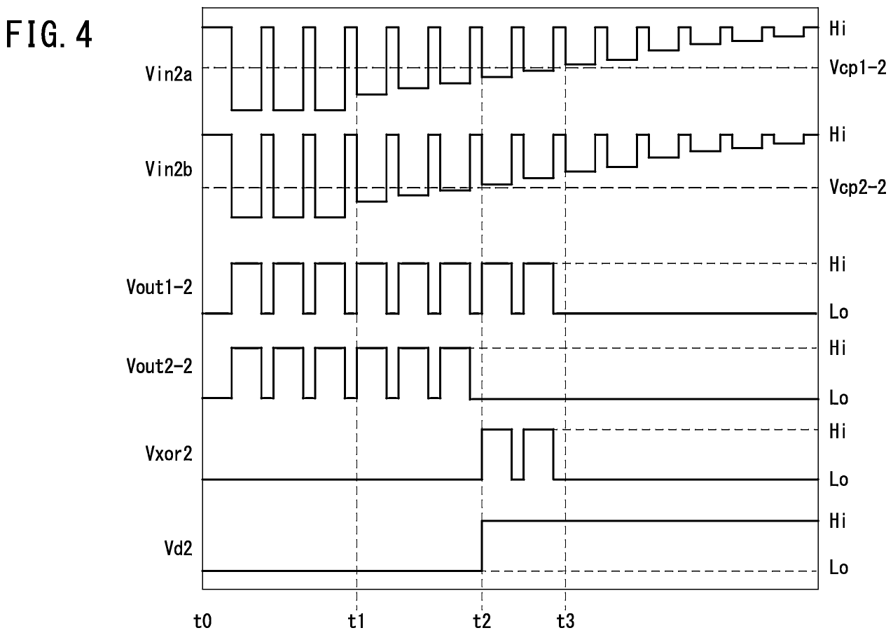

The operation of the control circuit 1A according to the present embodiment will be described with reference to FIGS. 3, 4 as well as FIGS. 1, 2. In the control circuit 1A, the detection operation to detect the defective state of the photo coupler 21 in the high-side control IC 7A is the same as the detection operation to detect the defective state of the photo coupler 22 in the low-side control IC 8A. On this account, the following describes the operation of the control circuit 1A by taking, as an example, the detection operation to detect the defective state of the photo coupler 22 in the low-side control IC 8A, that is, the detection operation to detect the defective state of the photo coupler 22 by the control circuit 1A. First described are the operations of the photo coupler 22 and the signal generating circuit 14-8 before and after the photo coupler 22 deteriorates, with reference to FIG. 3.

FIG. 3 is a view schematically illustrating input and output operation waveforms of the photo coupler 22 and an operation waveform of the signal generating circuit 14-8. In the first row in FIG. 3, a current waveform of a current Iin flowing through the light-emitting diode 221 provided in the photo coupler 22 is indicated, and in the second row in FIG. 3, a current waveform of a current Iout flowing through the photo diode 222 provided in the photo coupler 22 is indicated. In the third row in FIG. 3, respective voltage waveforms of a voltage Vin2 of the first input signal Sin2 generated in the signal generating circuit 14-8 and a voltage Vcp1-2 of the first compare signal Scp1-2 are indicated.

As illustrated in FIG. 2, the cathode K of the light-emitting diode 221 is connected to an output terminal of the NOT gate 31 via the signal output terminal T32 and the resistance element 32. Accordingly, when the voltage level of the input signal S2 input into the photo coupler 22 from the NOT gate 31 is at a high level, no current flows through the light-emitting diode 221. In the meantime, when the voltage level of the input signal S2 input into the photo coupler 22 from the NOT gate 31 is at a low level, a current flows through the light-emitting diode 221.

For example, when the voltage level of the input signal S2 is at the high level until time ta illustrated in FIG. 3, the current level of the current Iin flowing through the light-emitting diode 221 is at a low level (for example, a current value is 0 A) as indicated in the first row in FIG. 3. Accordingly, the light-emitting diode 221 does not emit light until time ta, so that the current level of the current Iout flowing through the photo diode 222 is at a low level (for example, a current value is 0 A). In a case where no current flows through the photo diode 222, no current flows through the base B (see FIG. 2) of the transistor 223 provided in the photo coupler 22, so that the transistor 223 is in an OFF state. Hereby, the voltage level of the control signal Sic2 output from the photo coupler 22 to the control circuit 1A via the low-side input terminal Tin2 is at a high level. As a result, a current output from the constant current source 141-8 (see FIG. 2) provided in the signal generating circuit 14-8 flows through the resistance elements 142-8, 143-8 (see FIG. 2) provided in the signal generating circuit 14-8, and the current hardly flows into the photo coupler 22 side. Accordingly, as indicated in the third row in FIG. 3, the voltage level of the voltage Vin2 of the first input signal Sin2 generated by the signal generating circuit 14-8 is at a high level until time ta.

When the voltage level of the input signal S2 is changed from the high level to the low level at time ta illustrated in FIG. 3, for example, the potential of the cathode K of the light-emitting diode 221 drops to a reference potential level, so that the current level of the current Iin flowing through the light-emitting diode 221 is turned to a high level as indicated in the first row in FIG. 3. As a result, the light-emitting diode 221 emits light after time ta, so that the current level of the current Iout flowing through the photo diode 222 is changed from the low level to a high level. In a case where the current flows through the photo diode 222, the current flows through the base B of the transistor 223 provided in the photo coupler 22, so that the transistor 223 is brought into an ON state. Hereby, the voltage level of the control signal Sic2 output from the photo coupler 22 to the control circuit 1A via the low-side input terminal Tin2 decreases. The decrease amount of the voltage level of the control signal Sic2 is determined by the current amount of the current flowing through the base B of the photo diode 222 and becomes larger as the current amount is larger.

In the meantime, in a case no deterioration occurs in the light-emitting diode 221, the current Iin of the current amount as indicated in the first row in FIG. 3 flows through the light-emitting diode 221 after time ta, so that the light-emitting diode 221 emits light at a desired intensity. Accordingly, as indicated by a broken line in the second row in FIG. 3, the current Iout at a current amount In1 flows through the photo diode 222. The current amount In1 is a current amount that can completely bring the transistor 223 into the ON state, for example. Because of this, the current output from the constant current source 141-8 flows through the transistor 223 and hardly flows through the resistance elements 142-8, 143-8 provided in the signal generating circuit 14-8. Accordingly, as indicated by a broken line in the third row in FIG. 3, the voltage level of the voltage Vin2 of the first input signal Sin2 generated by the signal generating circuit 14-8 decreases from time ta and reaches a voltage value Vin2n (for example, 0 V) at time tc.

In the meantime, even when the current Iin at the current amount as indicated in the first row in FIG. 3 flows through the light-emitting diode 221 after time ta, the intensity of light emitted from the light-emitting diode 221 having deterioration decreases in comparison with a case where no deterioration occurs. Accordingly, as indicated by a continuous line in the second row in FIG. 3, the current Iout at a current amount Idn1 flows through the photo diode 222. The current amount Idn1 is a current amount that can bring the transistor 223 into the ON state but cannot bring it into a completely ON state, for example. Hereby, part of the current output from the constant current source 141-8 flows into the transistor 223, and the remaining part of the current flows into the resistance elements 142-8, 143-8. Accordingly, the current at a current amount larger than the current amount before deterioration of the photo coupler 22 flows through the resistance element 143-8, so that the voltage drop in the resistance element 143-8 increases more than before the deterioration of the photo coupler 22. Hereby, as indicated by a continuous line in the third row in FIG. 3, the voltage level of the voltage Vin2 of the first input signal Sin2 generated by the signal generating circuit 14-8 decreases from time ta and reaches a voltage value Vin2d larger than the voltage value Vin2n at time tc. In other words, the drop amount of the voltage Vin2 of the first input signal Sin2 from time ta to time tc is smaller in a case where the photo coupler 22 deteriorates than in a case where the photo coupler 22 does not deteriorate.

FIG. 3 illustrates various waveforms in a case where the light-emitting diode 221 deteriorates, but in a case where the light-receiving sensitivity of the photo diode 222 decreases, the current amount of the current Iout flowing through the photo diode 222 also decreases. Accordingly, the voltage value Vin2d of the first input signal Sin2 changes in response to the deterioration degree of the photo coupler 22 such that the voltage value Vin2d is smaller as the deterioration degree of the deterioration is lower, and the voltage value Vin2d is larger as the deterioration degree is higher.

In the present embodiment, in a case where the control device 3 controls the IGBT 61 to the OFF state, the control device 3 outputs the input signal S2 the signal level of which is at the high level to the photo coupler 22, and in a case where the control device 3 controls the IGBT 61 to the ON state, the control device 3 outputs the input signal S2 the signal level of which is at the low level to the photo coupler 22. As described above, the gate drive circuit 81 (see FIG. 2) generates a gate drive signal for driving the IGBT 61 (see FIG. 1) based on the first output signal Sout1-2 input from the first determination circuit 13-8 (see FIG. 2). Accordingly, the voltage value of the first compare signal Scp1-2 generated by the compare signal generation section 132-8 is set to be larger than the voltage value Vin2n so that the first determination circuit 13-8 can determine whether the signal level of the control signal Sic2 reflecting the signal level of the input signal S2 input from the control device 3 is at the high level or at the low level.

Accordingly, in a case where the photo coupler 22 has no deterioration, the high-low relationship between the voltage Vin2 of the first input signal Sin2 input from the first determination circuit 13-8 and the voltage Vcp1-2 of the first compare signal Scp1-2 is reversed before and after time tb. As a result, the first determination circuit 13-8 outputs the first output signal Sout1-2 the voltage level of which is at the low level to the gate drive circuit 81 in a period (a period before time tb) during which the IGBT 61 is controlled to the OFF state as indicated by a leftward straight arrow in the third row in FIG. 3. Further, the first determination circuit 13-8 outputs the first output signal Sout1-2 the voltage level of which is at the high level to the gate drive circuit 81 in a period (a period after time tb) during which the IGBT 61 is controlled to the ON state as indicated by a rightward straight arrow in the third row in FIG. 3. Thus, in a case where when the photo coupler 22 has no deterioration, the control circuit 1A can output, to the gate drive circuit 81, the first output signal Sout1-2 having a voltage level corresponding to the control of the control device 3.

In the meantime, when the deterioration of the photo coupler 22 progresses, the voltage Vin2 of the first input signal Sin2 increases. Accordingly, in a case where the photo coupler 22 deteriorates and the voltage value Vin2d of the first input signal Sin2 becomes larger than the voltage value Vcp1 of the first compare signal Scp1-2, even when the signal level of the input signal S2 input from the control device 3 into the photo coupler 22 is changed from the high level to the low level, the first determination circuit 13-8 outputs, to the gate drive circuit 81, the first output signal Sout1-2 the voltage level of which is at the high level. That is, the first determination circuit 13-8 outputs, to the gate drive circuit 81, the first output signal Sout1-2 the voltage level of which is at the high level before and after time tb. Accordingly, as indicated by bidirectional straight arrows in the third row in FIG. 3, the gate drive circuit 81 outputs, to the IGBT 61, the gate drive signal to bring the IGBT 61 into the OFF state before and after time tb. As a result, even in a case where the control device 3 outputs, to the photo coupler 22, the input signal S2 to change the IGBT 61 from the OFF state to the ON state, when the photo coupler 22 has deterioration, the IGBT 61 maintains the OFF state, so that the IGBT 61 cannot operate in response to the control of the control device 3.

The signal level of the first input signal Sin2 increases as the deterioration of the photo coupler 22 progresses more. The photo coupler defect detecting circuit 11A-8 provided in the control circuit 1A detects the defective state of the photo coupler 22 in a stepwise manner by use of the characteristic of the first input signal Sin2 reflecting the deterioration degree of the photo coupler 22.

Next will be described an example of the detection operation to detect the defective state of the photo coupler 22 by the control circuit 1A with reference to FIG. 4 as well as FIGS. 1 to 3. FIG. 4 is a timing chart schematically illustrating an example of the operation waveform of the control circuit 1A in a case where the defective state of the photo coupler 22 due to long-term deterioration is detected. The first row in FIG. 4 indicates respective voltage waveforms of a voltage Vin2a of the first input signal Sin2 and the voltage Vcp1-2 of the first compare signal Scp1-2, input into the first comparator 131-8. The second row in FIG. 4 indicates respective voltage waveforms of a voltage Vin2b of the first input signal Sin2 and a voltage Vcp2-2 of the second compare signal Scp2-2, input into the second comparator 111-8. The third row in FIG. 4 indicates the voltage waveform of a voltage Vout1-2 of the first output signal Sout1-2. The fourth row in FIG. 4 indicates the voltage waveform of a voltage Vout2-2 of the second output signal Sout2-2. The fifth row in FIG. 4 illustrates the voltage waveform of a voltage Vxor2 of the operation result signal Sxor2. The sixth row in FIG. 4 indicates the voltage waveform of a voltage Vd2 of the defect detecting signal Sd2. The operating time of the photo coupler 22 is illustrated on the horizontal axis in the graph illustrated in FIG. 4, and the voltage in each of the first to sixth rows are illustrated on the vertical axis in the graph illustrated FIG. 4. In the graph illustrated in FIG. 4, time elapses from the left to the right. Note that, when an accumulated operation period reaches several years, the photo coupler 22 starts to deteriorate. In FIG. 4, in order to facilitate understanding, the time axis on the horizontal axis ignores the accumulated operation period required for deterioration of the photo coupler 22.

In the control circuit 1A, respective first input signals Sin2 input into respective inverting input terminals (−) of the first comparator 131-8 and the second comparator 111-8 are the same signal (see FIG. 2). Accordingly, as illustrated in FIG. 4, a voltage input into the inverting input terminal (−) of the first comparator 131-8 is the same voltage as a voltage input into the inverting input terminal (−) of the second comparator 111-8. However, in FIG. 4, for convenience of this description, these voltages are indicated by reference sign “V2a” and reference sign “V2b” that are different from each other.

The first compare signal Scp1-2 and the second compare signal Scp2-2 are set to different signal levels. In the control circuit 1A, the voltage Vcp1-2 of the first compare signal Scp1-2 and the voltage Vcp2-2 of the second compare signal Scp2-2 are set to be different from each other, so that the signal level of the first compare signal Scp1-2 and the signal level of the second compare signal Scp2-2 are set to be different from each other. More specifically, in the control circuit 1A, the voltage Vcp1-2 of the first compare signal Scp1-2 is set to be higher than the voltage Vcp2-2 of the second compare signal Scp2-2.

In FIG. 4, a period during which the voltage levels of the voltages Vin2a, Vin2b are at a high level Hi is a period during which the control device 3 (see FIG. 1) is to control the IGBT 61 (see FIG. 1) to the OFF state. In the meantime, a period during which the voltage levels of the voltages Vin2a, Vin2b are not at the high level Hi is a period during which the control device 3 is to control the IGBT 61 to the ON state. Hereinafter, in the description of the present embodiment, for convenience of this description, the “period during which the voltage levels of the voltages Vin2a, Vin2b are at the high level Hi” is referred to as a “high-level period,” and the “period during which the voltage levels of the voltages Vin2a, Vin2b are not at the high level Hi” is referred to as a “low-level period.” Accordingly, the high-level period is a period during which the current Iin (see FIG. 2) does not flow through the light-emitting diode 221 provided in the photo coupler 22. In the meantime, the low-level period is a period during which the current Iin flows through the light-emitting diode 221 provided in the photo coupler 22.

As illustrated in FIG. 4, in a period from time t0 to time t1, the high-level period and the low-level period are repeated at predetermined timings. Accordingly, in the period from time t0 to time t1, the period during which the current Iin does not flow through the light-emitting diode 221 and the period during which the current Iin flows through the light-emitting diode 221 are repeated at the predetermined timings.

The photo coupler 22 does not deteriorate in the period from t0 to time t1. Accordingly, as illustrated in FIG. 4, in the period from time t0 to time t1, the voltages Vin2a, Vin2b of the first input signal Sin2 generated by the signal generating circuit 14-8 (see FIG. 2) provided in the control circuit 1A (see FIG. 2) are lower than the voltage Vcp1-2 of the first compare signal Scp1-2 and the voltage Vcp2-2 of the second compare signal Scp2-2 in the low-level period. Accordingly, the voltage level of the operation result signal Sxor2 output from the XOR gate 113-8 (see FIG. 2) reaches a low level Lo. The latch circuit 114-8 (see FIG. 2) does not receive the operation result signal Sxor2 the voltage level of which is at the high level before time t0. On this account, in the low-level period during the period from time t0 to time t1, the voltage level of the voltage Vd2 of the defect detecting signal Sd2 output from the latch circuit 114-8 is at the low level Lo.

In a case where respective voltage levels of the voltage Vxor2 of the operation result signal Sxor2 and the voltage Vd2 of the defect detecting signal Sd2, input from the photo coupler defect detecting circuit 11A-8, are at the low level Lo, the warning output circuit 12 (see FIG. 2) determines that the photo coupler 22 does not deteriorate. In the period from time t0 to time t1, the warning output circuit 12 receives, from the photo coupler defect detecting circuit 11A-8, the operation result signal Sxor2 having the voltage Vxor2 the voltage level of which is at the low level Lo, and the defect detecting signal Sd2 having the voltage Vd2 the voltage level of which is at the low level Lo. Accordingly, the warning output circuit 12 does not output the alarm signal Sarm to notify the deterioration of the photo coupler 22 to the control device 3 in the period from to to time t1.

As has been described with reference to FIG. 3, in the low-level period, the voltage levels of the voltages Vin2a, Vin2b of the first input signal Sin2 generated by the signal generating circuit 14-8 provided in the control circuit 1A increase more after the photo coupler 22 deteriorates than before the photo coupler 22 deteriorates. Accordingly, when the photo coupler 22 starts to deteriorate at time t1, for example, the voltage levels of the voltages Vin2a, Vin2b increase in the low-level period, as illustrated in FIG. 4. Even when the voltage levels of the voltages Vin2a, Vin2b increase in the low-level period after time t1, the voltage Vin2a is lower than the voltage Vcp1-2 of the first compare signal Scp1-2, and the voltage Vin2b is lower than the voltage Vcp2-2 of the second compare signal Scp2-2 similarly to the period before time t1. Accordingly, before and after the start of deterioration of the photo coupler 22 (i.e., before and after time t1), the voltage Vout1-2 of the first output signal Sout1-2 and the voltage Vout2-2 of the second output signal Sout2-2 are both at the high level Hi in the low-level period.

Further, before and after the start of deterioration of the photo coupler 22 (i.e., before and after time t1), the voltage levels of the voltages Vout1-2, Vout2-2 are both at the high level Hi. Accordingly, as illustrated in FIG. 4, before and after the start of deterioration of the photo coupler 22, the voltage level of the voltage Vxor2 of the operation result signal Sxor2 is at the low level Lo, and the voltage level of the voltage Vd2 of the defect detecting signal Sd2 output from the latch circuit 114-8 is also at the low level Lo.

Even when time t1 has passed and the photo coupler 22 starts to deteriorate, the warning output circuit 12 receives, from the photo coupler defect detecting circuit 11A-8, the operation result signal Sxor2 having the voltage Vxor2 the voltage level of which is at the low level Lo, and the defect detecting signal Sd2 having the voltage Vd2 the voltage level of which is at the low level Lo. Accordingly, the warning output circuit 12 does not output the alarm signal Sarm to notify the deterioration of the photo coupler 22 to the control device 3 even after time t1.

When the photo coupler 22 operates to cause the IGBT 61 to perform the switching operation until time t2 after a predetermined time passes from time t1, the deterioration degree of the photo coupler 22 further progresses. Accordingly, after time t2, the first input signal Sin2 in the low-level period is lower than the first compare signal Scp1-2 but higher than the second compare signal Scp2-2. More specifically, as illustrated in FIG. 4, at time t2, in the first comparator 131-8, the voltage Vin2a of the first input signal Sin2 is lower than the voltage Vcp1-2 of the first compare signal Scp1-2, and in the second comparator 111-8, the voltage Vin2b of the first input signal Sin2 is higher than the voltage Vcp2-2 of the second compare signal Scp2-2.

Accordingly, at time t2 after the deterioration of the photo coupler 22 further progresses from time t1, the voltage level of the voltage Vout1-2 of the first output signal Sout1-2 is at the high level Hi in the low-level period. In the meantime, at time t2, the voltage level of the voltage Vout2-2 of the second output signal Sout2-2 is at the low level Lo in the low-level period. Hereby, at time t2, the voltage level of the voltage Vxor2 of the operation result signal Sxor2 reaches the high level Hi. The latch circuit 114-8 receives the operation result signal Sxor2 having the voltage Vxor2 at the high level Hi, and therefore, the latch circuit 114-8 outputs, to the warning output circuit 12, the defect detecting signal Sd2 having the voltage Vd2 at the high level Hi.

In a case where respective voltage levels of the voltage Vxor2 of the operation result signal Sxor2 and the voltage Vd2 of the defect detecting signal Sd2, input from the photo coupler defect detecting circuit 11A-8, are at the high level, the warning output circuit 12 determines that the photo coupler 22 is at a deterioration alarm level. Here, the “deterioration alarm level” indicates that, although the IGBT 61 can perform the switching operation in response to the control of the control device 3, it is necessary to notify that the photo coupler 22 starts to deteriorate.

At time t2, the warning output circuit 12 receives, from the photo coupler defect detecting circuit 11A-8, the operation result signal Sxor2 having the voltage Vxor2 the voltage level of which is at the high level Hi, and the defect detecting signal Sd2 having the voltage Vd2 the voltage level of which is at the high level Hi. Accordingly, the warning output circuit 12 outputs, to the control device 3, the alarm signal Sarm to notify that the deterioration of the photo coupler 22 progresses to the deterioration alarm level.

When the photo coupler 22 operates to cause the IGBT 61 to perform the switching operation until time t3 after a predetermined time passes from time t2, the deterioration degree of the photo coupler 22 further progresses. However, in the low-level period during a period from time t2 to time t3, the voltages Vin2a and Vin2b of the first input signal Sin2 are lower than the voltage Vcp1-2 of the first compare signal Scp1-2, whereas the voltages Vin 2a and Vin2b of the first input signal Sin2 are higher than the voltage Vcp2-2 of the second compare signal Scp2-2. Accordingly, the first comparator 131-8 and the photo coupler defect detecting circuit 11A-8 operate similarly to the operations at time t2, so that the warning output circuit 12 keeps outputting, to the control device 3, the alarm signal Sarm to notify that the photo coupler 22 is at the deterioration alarm level.

When the photo coupler 22 operates to cause the IGBT 61 to perform the switching operation until time t3 after a predetermined time passes from time t2, the deterioration degree of the photo coupler 22 further progresses. Accordingly, in the low-level period at time t3, the voltage levels of the first input signal Sin2 become higher than the voltage Vcp1-2 of the first compare signal Scp1-2 and the voltage Vcp2-2 of the second compare signal Scp2-2. More specifically, as illustrated in FIG. 4, at time t3, in the first comparator 131-8, the voltage Vin2a of the first input signal Sin2 becomes higher than the voltage Vcp1-2 of the first compare signal Scp1-2, and in the second comparator 111-8, the voltage Vin2b of the first input signal Sin2 is kept higher than the voltage Vcp2-2 of the second compare signal Scp2-2.

Accordingly, at time t3 after the deterioration of the photo coupler 22 further progresses from time t2, the voltage Vout1-2 of the first output signal Sout1-2 is at the low level Lo in the low-level period. Further, at time t3, the voltage Vout2-2 of the second output signal Sout2-2 is at the low level Lo in the low-level period. Hereby, at time t3, the voltage level of the voltage Vxor2 of the operation result signal Sxor2 is at the low level Lo. The latch circuit 114-8 receives the operation result signal Sxor2 having the voltage Vxor2 the voltage level of which is at the high level Hi before time t3. Accordingly, even when the latch circuit 114-8 receives the operation result signal Sxor2 having the voltage Vxor2 the voltage level of which is at the low level Lo, the latch circuit 114-8 outputs, to the warning output circuit 12, the defect detecting signal Sd2 having the voltage Vd2 the voltage level of which is at the high level Hi.

As described above, the photo coupler defect detecting circuit 11A-8 outputs, to the warning output circuit 12, the operation result signal Sxor2 and the defect detecting signal Sd2 generated by the operation result signal Sxor2. The operation result signal Sxor2 is a signal obtained by performing an exclusive-OR operation on the signal level of the first output signal Sout1-2 and the signal level of the second output signal Sout2-2. The defect detecting signal Sd2 is a signal based on the first output signal Sout1-2 and the second output signal Sout2-2. Accordingly, the photo coupler defect detecting circuit 11A-8 detects the defective state of the photo coupler 22 based on the first output signal Sout1-2 output from the first comparator 131-8 and the second output signal Sout2-2 output from the second comparator 111-8.

The first output signal Sout1-2 is a comparison result signal obtained by the first comparator 131-8 comparing the first input signal Sin2 with the first compare signal Scp1-2. That is, the first output signal Sout1-2 is a signal based on the first input signal Sin2. Accordingly, the photo coupler defect detecting circuit 11A-8 detects the defective state of the photo coupler 22 based on the first input signal Sin2 and the first output signal Sout1-2 output from the first determination circuit 13-8.

In a case where the voltage level of the voltage Vxor2 of the operation result signal Sxor2 input from the photo coupler defect detecting circuit 11A-8 is at the low level Lo and the voltage level of the voltage Vd2 of the defect detecting signal Sd2 is at the high level Hi, the warning output circuit 12 determines that the photo coupler 22 is in a deteriorated state. Here, the “deteriorated state” indicates a state where the photo coupler 22 deteriorates to such an extent that the IGBT 61 cannot perform the switching operation in response to the control of the control device 3.

At time t3, the warning output circuit 12 receives, from the photo coupler defect detecting circuit 11A-8, the operation result signal Sxor2 having the voltage Vxor2 the voltage level of which is at the low level Lo, and the defect detecting signal Sd2 having the voltage Vd2 the voltage level of which is at the high level Hi. Accordingly, the warning output circuit 12 outputs, to the control device 3, the alarm signal Sarm to notify that the deterioration of the photo coupler 22 progresses and the photo coupler 22 is in the deteriorated state.

When the photo coupler 22 operates to cause the IGBT 61 to perform the switching operation after time t3, the deterioration degree of the photo coupler 22 further progresses. Accordingly, in the low-level period, the voltage Vin2a of the first input signal Sin2 is maintained to be higher than the voltage Vcp1-2 of the first compare signal Scp1-2, and the voltage Vin2b of the first input signal Sin2 is also maintained to be higher than the second compare signal Scp2-2. Accordingly, the first comparator 131-8 and the photo coupler defect detecting circuit 11A-8 operate similarly to the operations at time t3, so that the warning output circuit 12 keeps outputting, to the control device 3, the alarm signal Sarm to notify that the photo coupler 22 is in the deteriorated state.

TABLE 1

| CONTROL | | | | | STATE OF |
|---|---|---|---|---|---|
| STATE OF | | | | | PHOTO |
| IGBT | Vout1-2 | Vout2-2 | Vxor2 | Vd2 | COUPLER |
| ON | High | High | Low | Low | NO PROBLEM |
| OFF | Low | Low | Low | Low | |
| ON | High | Low | High | High | DETERIORATION |
| OFF | Low | Low | Low | High | ALARM LEVEL |
| ON | Low | Low | Low | High | DETERIORATED |
| OFF | Low | Low | Low | High | STATE |

Table 1 is a truth table of voltage levels of respective portions at the time when the control circuit 1A detects the defective state of the photo coupler 22. In Table 1, “CONTROL STATE OF IGBT” indicates a control state where the IGBT 61 is controlled by the control device 3. Further, “Vout1-2” in Table 1 indicates the voltage of the first output signal Sout1-2, and “Vout2-2” in Table 1 indicates the voltage of the second output signal Sout2-2. “Vxor2” in Table 1 indicates the voltage of the operation result signal Sxor2, and “Vd2” in Table 1 indicates the voltage of the defect detecting signal Sd2. “STATE OF PHOTO COUPLER” in Table 1 indicates the state of the photo coupler 22. “High” in Table 1 indicates that the voltage level of a corresponding voltage is at the high level, and “Low” in Table 1 indicates that the voltage level of a corresponding voltage is at the low level. “ON” in Table 1 indicates that the IGBT 61 is controlled to the ON state, and “OFF” in Table 1 indicates that the IGBT 61 is controlled to the OFF state. “NO PROBLEM” in FIG. 1 indicates a normal state where the photo coupler 22 does not deteriorate. “DETERIORATION ALARM LEVEL” and “DETERIORATED STATE” in FIG. 1 are similar to the “deterioration alarm level” and the “deteriorated state” described with reference to FIG. 4.

As has been described with reference to FIG. 4, the control circuit 1A notifies the defective state of the photo coupler 22 in a stepwise manner in response to the deterioration level of the photo coupler 22. A period during which respective voltage levels of the voltage Vxor2 of the operation result signal Sxor2 and the voltage Vd2 of the defect detecting signal Sd2 in Table 1 are at the low level corresponds to the period from time t0 to time t1 (a period during which the photo coupler 22 does not deteriorate) in FIG. 4, and the period from time t1 to time t2 (a period during which the photo coupler 22 deteriorates to such an extent that it is not necessary to notify the deterioration of the photo coupler 22) in FIG. 4. Accordingly, as illustrated in Table 1, in the period during which respective voltage levels of the voltage Vxor2 of the operation result signal Sxor2 and the voltage Vd2 of the defect detecting signal Sd2 are at the low level, the state of the photo coupler has “NO PROBLEM.”

Further, in terms of the period during which the IGBT 61 is controlled to the ON state (that is, the low-level period as described with reference to FIG. 4) in Table 1, in a period during which the voltage level of the voltage Vout1-2 of the first output signal Sout1-2 is at the high level and the voltage level of the voltage Vout2-2 of the second output signal Sout2-2 is at the low level, respective voltage levels of the voltage Vxor2 of the operation result signal Sxor2 and the voltage Vd2 of the defect detecting signal Sd2 are both at the high level. This period corresponds to the period from time t2 to time t3 (a period during which the deterioration of the photo coupler 22 progresses though the IGBT 61 can perform the switching operation in response to the control of the control device 3) in FIG. 4. As illustrated in Table 1, during this period, the state of the photo coupler is “DETERIORATION ALARM LEVEL.”

Further, in terms of the period during which the IGBT 61 is controlled to the ON state (that is, the low-level period as described with reference to FIG. 4) in Table 1, in a period during which respective voltage levels of the voltage Vout1-2 of the first output signal Sout1-2 and the voltage Vout2-2 of the second output signal Sout2-2 are at the low level, the voltage level of the voltage Vxor2 of the operation result signal Sxor2 is at the low level, and the voltage level of the voltage Vd2 of the defect detecting signal Sd2 is at the high level. This period corresponds to the period after time t3 (a period during which the deterioration of the photo coupler 22 progresses to such an extent that the IGBT 61 cannot perform the switching operation in response to the control of the control device 3) in FIG. 4. As illustrated in Table 1, the state of the photo coupler is “DETERIORATED STATE” in this period.

As has been described with reference to FIG. 4 and Table 1, the photo coupler defect detecting circuit 11A-8 can detect the degree of the deterioration progress of the photo coupler 22 in a stepwise manner by changing respective signal levels (voltage levels in the present embodiment) of the operation result signal Sxor2 and the defect detecting signal Sd2. At the time of detection of the deterioration of the photo coupler 22, the photo coupler defect detecting circuit 11A-8 can detect the defective state of the photo coupler 22 while the IGBT 61 controlled based on the control signal Sic2 input from the photo coupler 22 via the low-side input terminal Tin2 performs the switching operation.

For example, the period from time t2 to time t3 in FIG. 4 is a period during which the voltage level of the voltage Vout1-2 of the first output signal Sout1-2 is repeatedly changed between the high level Hi and the low level Lo in response to the signal level of the control signal Sic2. The gate drive circuit 81 generates a gate drive signal for causing the IGBT 61 to perform the switching operation by use of the first output signal Sout1-2 input from the first comparator 131-8. Accordingly, in this period, the gate drive circuit 81 can drive the IGBT 61 by the switching operation based on changes in the signal level of the control signal Sic2. In the meantime, in the period from time t2 to time t3, the photo coupler defect detecting circuit 11A-8 outputs, to the warning output circuit 12, the operation result signal Sxor2 the signal level of which is at the high level and the defect detecting signal Sd2 the signal level of which is at the high level, so that it is possible to detect the state of the photo coupler 22 being at the deterioration alarm level as illustrated in Table 1.

Even in a period during which the IGBT 61 does not perform the switching operation after the defective state of the photo coupler 22 is detected (that is, a period after time t3 illustrated in FIG. 4), the photo coupler defect detecting circuit 11A-8 can detect the photo coupler 22 being in the deteriorated state. That is, in the period during which the IGBT 61 does not perform the switching operation after the defective state of the photo coupler 22 is detected, the photo coupler defect detecting circuit 11A-8 outputs, to the warning output circuit 12, the operation result signal Sxor2 the signal level of which is at the low level Lo and the defect detecting signal Sd2 the signal level of which is at the high level, so that it is possible to detect the photo coupler 22 being in “DETERIORATED STATE” as illustrated in Table 1.

The warning output circuit 12 can notify that the defective state of the photo coupler 22 is detected by the photo coupler defect detecting circuit 11A-8 while the IGBT 61 performs the switching operation. As described above, in the period during which the gate drive circuit 81 can drive the IGBT 61 by the switching operation based on changes in the signal level of the control signal Sic2 (that is, the period from time t2 to time t3 in FIG. 4), the warning output circuit 12 receives, from the photo coupler defect detecting circuit 11A-8, the operation result signal Sxor2 the signal level of which is at the high level and the defect detecting signal Sd2 the signal level of which is at the high level. Accordingly, in this period, the warning output circuit 12 can output, to the control device 3, the alarm signal Sarm to notify that the state of the photo coupler 22 is at the deterioration alarm level.

In a case where the degree of the defective state of the photo coupler 22, detected by the photo coupler defect detecting circuit 11A-8, is within a predetermined range while the IGBT 61 performs the switching operation, the warning output circuit 12 notifies that the defective state is detected by the photo coupler defect detecting circuit 11A-8 while the IGBT 61 continues the switching operation. Here, that the degree of the defective state of the photo coupler 22 is within the predetermined range indicates that the state of the photo coupler 22 is at the deterioration alarm level. The control circuit 1A detects whether or not the degree of the defective state of the photo coupler 22 is within the predetermined range, that is, whether or not the state of the photo coupler 22 is at the deterioration alarm level, based on the change amount of the voltage level of the voltage Vin2a (the voltage Vin2b) of the first input signal Sin2 in a period during which the IGBT 61 is controlled to the ON state. That is, in a case where the voltage Vin2a (the voltage Vin2b) of the first input signal Sin2 is in a voltage range between the voltage Vcp1-2 of the first compare signal Scp1-2 and the voltage Vcp2-2 of the second compare signal Scp2-2, the control circuit 1A detects the degree of the defective state of the photo coupler 22 being within the predetermined range, that is, the state of the photo coupler 22 being at the deterioration alarm level.

A period during which the voltage Vin2a (the voltage) Vin2b) of the first input signal Sin2 falls within the voltage range between the voltage Vcp1-2 of the first compare signal Scp1-2 and the voltage Vcp2-2 of the second compare signal Scp2-2 corresponds to the period from time t2 to time t3 in FIG. 4. As described above, the IGBT 61 performs the switching operation in the period from time t2 to time t3. Accordingly, the photo coupler defect detecting circuit 11A-8 detects the defective state of the photo coupler 22 which defective state progresses to such an extent that the voltage Vin2a (the voltage Vin2b) of the first input signal Sin2 falls within the voltage range. In this case, the warning output circuit 12 outputs the alarm signal Sarm to notify that the photo coupler defect detecting circuit 11A-8 detects the state of the photo coupler 22 being at the deterioration alarm level while the IGBT 61 continues the switching operation.

Even after the voltage Vin2a (the voltage Vin2b) of the first input signal Sin2 deviates from the voltage range and becomes higher than respective voltages of the first compare signal Scp1-2 and the second compare signal Scp2-2, and the IGBT 61 stops the switching operation, unless the photo coupler 22 is replaced, the warning output circuit 12 outputs the alarm signal Sarm to notify that the photo coupler defect detecting circuit 11A-8 detects the photo coupler 22 being in the deteriorated state.

The detection of the defective state of the photo coupler 21, 22 in the control circuit 1A has been described above by taking, as an example, the detection of the defective state of the photo coupler 22 by the photo coupler defect detecting circuit 11A-8. Although detailed descriptions are omitted herein, the photo coupler defect detecting circuit 11A-7 can detect the defective state of the photo coupler 21 in a stepwise manner (i.e., the deterioration alarm level and the deteriorated state) by an operation similar to that of the photo coupler defect detecting circuit 11A-8. Further, the warning output circuit 12 can notify the defective state of the photo coupler 21 in a stepwise manner (i.e., the deterioration alarm level and the deteriorated state) based on respective signal levels of the operation result signal Sxor1 and the defect detecting signal Sd1 input from the photo coupler defect detecting circuit 11A-7.

As described above, the control circuit 1A according to the present embodiment includes the photo coupler defect detecting circuit 11A-7, 11A-8 configured to detect a defective state including deterioration and abnormality of the photo coupler 21, 22, and the warning output circuit 12 configured to notify that the defective state of the photo coupler 21, 22 is detected by the photo coupler defect detecting circuit 11A-7, 11A-8.

Further, the semiconductor module SMA according to the present embodiment includes the control circuit 1A according to the present embodiment, the IGBT 51 controlled based on the control signal Sic1, and the IGBT 61 based on the control signal Sic2.

With the control circuit 1A and the semiconductor module SMA having such a configuration, it is possible to control detection of a defective state caused due to the life of the photo coupler 21, 22.

### Second Embodiment

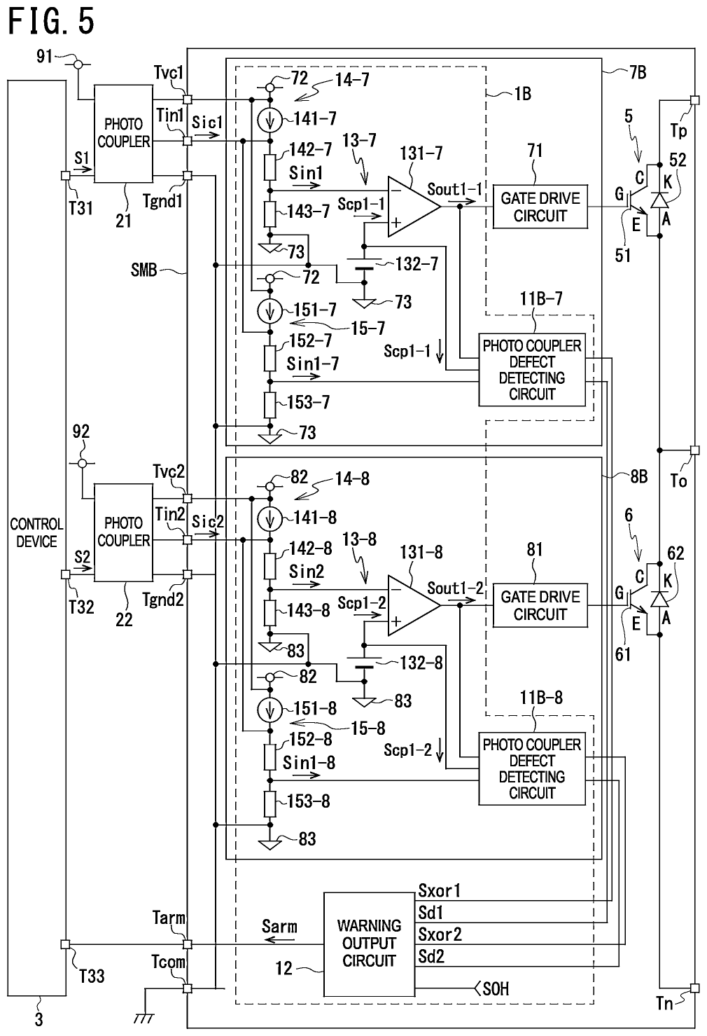

A control circuit and a semiconductor module according to a second embodiment of the present invention will be described with reference to FIGS. 5 to 7. Hereinafter, in terms of constituents of the control circuit and the semiconductor module according to the present embodiment, a constituent having the same operation and function as a constituent of the control circuit and the semiconductor module according to the first embodiment is referred to as the same reference sign as used in the first embodiment, and the description thereof is omitted.

### [Configuration of Semiconductor Module]

The schematic configuration of a semiconductor module SMB according to the present embodiment will be described with reference to FIG. 5.

As illustrated in FIG. 5, the semiconductor module SMB has a configuration similar to the configuration of the semiconductor module SMA according to the first embodiment except that the semiconductor module SMB includes a control circuit 1B having a configuration different from that of the control circuit 1A. That is, the semiconductor module SMB includes the control circuit 1B according to the present embodiment. The semiconductor module SMB also includes the IGBT 51 (an example of the semiconductor switching element) controlled based on the control signal Sic1, and the IGBT 61 (an example of the semiconductor switching element) controlled based on the control signal Sic2.

The control circuit 1B has a configuration different from that of the control circuit 1A, so that the semiconductor module SMB includes a high-side control IC 7B configured differently from the high-side control IC 7A, and a low-side control IC 8B configured differently from the low-side control IC 8A.

As illustrated in FIG. 5, the high-side control IC 7B has a signal generating circuit 15-7 that is one of the constituents of the control circuit 1B, and a photo coupler defect detecting circuit 11B-7 configured differently from the photo coupler defect detecting circuit 11A-7 in the first embodiment. The low-side control IC 8B has a signal generating circuit 15-8 that is one of the constituents of the control circuit 1B, and a photo coupler defect detecting circuit 11B-8 configured differently from the photo coupler defect detecting circuit 11A-8. Details of the signal generating circuits 15-7, 15-8 and the photo coupler defect detecting circuits 11B-7, 11B-8 will be described later.

### [Configuration of Control Circuit]

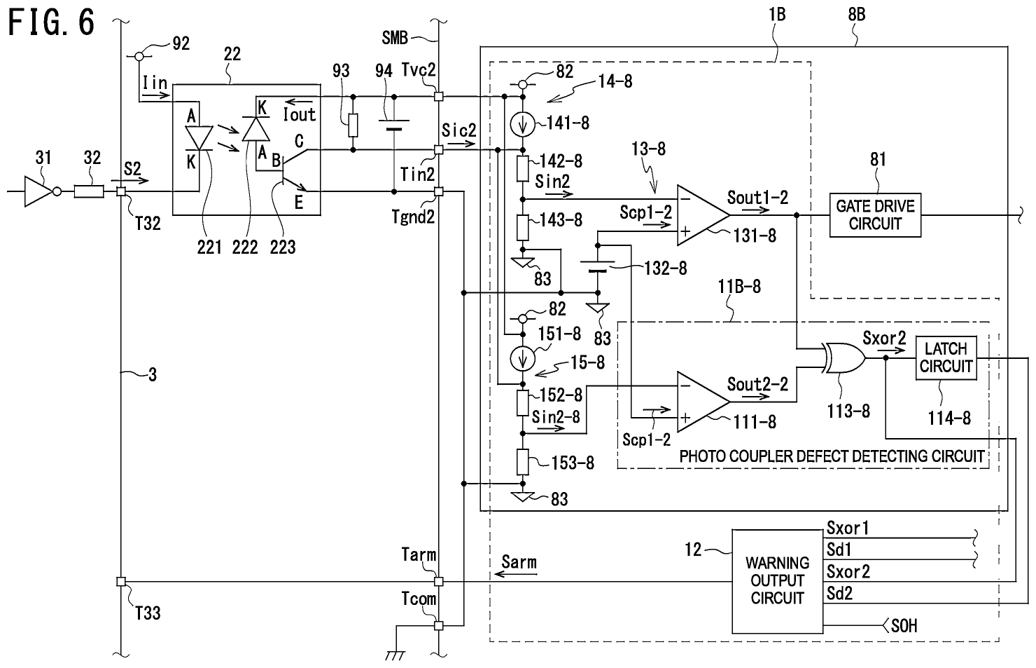

The schematic configuration of the control circuit 1B according to the present embodiment will be described with reference to FIG. 6 as well as FIG. 5. The signal generating circuit 14-7, the first determination circuit 13-7, and the photo coupler defect detecting circuit 11B-7 provided in the high-side control IC 7B as constituents of the control circuit 1B for detecting the defective state of the photo coupler 21 and the signal generating circuit 14-8, the first determination circuit 13-8, and the photo coupler defect detecting circuit 11B-8 provided in the low-side control IC 8B as constituents of the control circuit 1B for detecting the defective state of the photo coupler 22 have the same configurations. Accordingly, in the description of the control circuit 1B, concrete configurations of the signal generating circuit 14-7, the first determination circuit 13-7, and the photo coupler defect detecting circuit 11B-7 are not described.

As illustrated in FIG. 6, the control circuit 1B includes a signal generating circuit 15-8 configured to generate a second input signal Sin2-8 having a signal level different from that of the first input signal Sin2 generated by the signal generating circuit 14-8 and based on the control signal Sic2. The signal generating circuit 15-8 includes a constant current source 151-8, a resistance element 152-8, and a resistance element 153-8 serially connected between the power supply terminal 82 and the reference potential terminal 83. The power supply terminal 82 is a terminal configured to supply a power supply voltage to the low-side control IC 8B. The reference potential terminal 83 is a terminal configured to supply a reference potential to the low-side control IC 8B. A power-supply-side terminal of the constant current source 151-8 is connected to the power supply terminal 82, and an output terminal of the constant current source 151-8 is connected to one terminal of the resistance element 152-8. The other terminal of the resistance element 152-8 is connected to one terminal of the resistance element 153-8, and the other terminal of the resistance element 153-8 is connected to the reference potential terminal 83. The signal generating circuit 15-8 generates a signal having a voltage level of a voltage dropped in the resistance element 153-8 due to a current flowing from the constant current source 151-8 side, as the second input signal Sin2-8 based on the control signal Sic2.

The power-supply-side terminal of the constant current source 151-8 and the power supply terminal 82 are connected to the low-side power supply terminal Tvc2. The output terminal of the constant current source 151-8 and the one terminal of the resistance element 152-8 are connected to the low-side input terminal Tin2. The other terminal of the resistance element 153-8 and the reference potential terminal 83 are connected to the low-side ground terminal Tgnd2 and the common reference potential terminal Tcom. Accordingly, the reference potential of the low-side control IC 8B is the same potential as a reference potential input from the common reference potential terminal Tcom.

A resistance value of a combined resistance of the resistance element 152-8 and the resistance element 153-8 is set to be the same as a resistance value of a combined resistance of the resistance element 142-8 and the resistance element 143-8 provided in the signal generating circuit 14-8 and is also set such that the resistance value of the resistance element 153-8 is larger than the resistance value of the resistance element 143-8. Further, the constant current source 151-8 is configured to output a constant current at the same current amount as a constant current output from the constant current source 141-8. Accordingly, the signal level of the second input signal Sin2-8 generated by the signal generating circuit 15-8 is higher than the signal level of the first input signal Sin2 generated by the signal generating circuit 14-8.

As illustrated in FIG. 6, the control circuit 1B includes the first determination circuit 13-8 having the same configuration as the first determination circuit 13-8 in the first embodiment. The first determination circuit 13-8 in the present embodiment has the first comparator 131-8 configured to compare the signal level of the first input signal Sin2 with the signal level of the first compare signal Scp1-2 set at a predetermined signal level. The first determination circuit 13-8 has the compare signal generation section 132-8 configured to generate the first compare signal Scp1-2.

The control circuit 1B includes the photo coupler defect detecting circuit 11B-8 configured to detect a defective state including deterioration and abnormality of the photo coupler 22 (an example of the optical coupler). The photo coupler defect detecting circuit 11B-8 has the second comparator 111-8, the XOR gate 113-8, and the latch circuit 114-8.

The second comparator 111-8 compares the second input signal Sin2-8 having a signal level different from that of the first input signal Sin2 and based on the control signal Sic2 with the signal level of the first compare signal Scp1-2. The noninverting input terminal (+) of the second comparator 111-8 is connected to the positive terminal of the compare signal generation section 132-8. The inverting input terminal (−) of the second comparator 111-8 is connected to the other terminal of the resistance element 152-8 and the one terminal of the resistance element 153-8. The output terminal of the second comparator 111-8 is connected to one input terminal of the XOR gate 113-8. Accordingly, the second comparator 111-8 compares the signal level of the second input signal Sin2-8 input from the signal generating circuit 15-8 with the signal level of the first compare signal Scp1-2 input from the compare signal generation section 132-8, in terms of voltage level. The second comparator 111-8 outputs the second output signal Sout2-2 based on a comparison result between the second input signal Sin2-8 and the first compare signal Scp1-2 to the XOR gate 113-8.

The signal generating circuit 14-8 and the signal generating circuit 15-8 both receive the same control signal Sic2, but the signal level of the second input signal Sin2-8 generated by the signal generating circuit 15-8 is higher than the signal level of the first input signal Sin2 generated by the signal generating circuit 14-8. Accordingly, when the deterioration of the photo coupler 22 progresses, the second input signal Sin2-8 becomes higher than the first compare signal Scp1-2 at a stage earlier than the first input signal Sin2. Accordingly, the signal level of the second output signal Sout2-2 output from the second comparator 111-8 reaches a low level at a stage earlier than the first output signal Sout1-2 output from the first comparator 131-8. Hereby, although the photo coupler defect detecting circuit 11B-8 uses the first compare signal Scp1-2 in common with the first comparator 131-8, the photo coupler defect detecting circuit 11B-8 can detect the deteriorated state of the photo coupler 22 in a stepwise manner.

Although detailed descriptions are omitted herein, as illustrated in FIG. 5, the signal generating circuit 15-7 has a configuration similar to that of the signal generating circuit 15-8 by reading the constant current source 151-8 as a constant current source 151-7, the resistance element 152-8 as a resistance element 152-7, the resistance element 153-8 as a resistance element 153-7, the power supply terminal 82 as the power supply terminal 72, the reference potential terminal 83 as the reference potential terminal 73, and the photo coupler defect detecting circuit 11B-8 as the photo coupler defect detecting circuit 11B-7. The power supply terminal 72 is a terminal configured to supply a power supply voltage to the high-side control IC 7B. The reference potential terminal 73 is a terminal configured to supply a reference potential to the high-side control IC 7B. Note that a power-supply-side terminal of the constant current source 151-7 is connected to the power supply terminal 72 and the high-side power supply terminal Tvc1. The other terminal of the resistance element 153-8 is connected to the reference potential terminal 73 and the high-side ground terminal Tgnd1.

The photo coupler defect detecting circuit 11B-7 has the same configuration as the photo coupler defect detecting circuit 11B-8. A noninverting input terminal of a second comparator (not illustrated) provided in the photo coupler defect detecting circuit 11B-7 is connected to a connecting portion between the resistance element 152-7 and the resistance element 153-7. An inverting input terminal of the second comparator is connected to the positive terminal of the compare signal generation section 132-8. One input terminal of an XOR gate (not illustrated) provided in the photo coupler defect detecting circuit 11B-7 is connected to an output terminal of the second comparator. The other input terminal of the XOR gate is connected to the output terminal of the first comparator 131-7. An output terminal of the XOR gate is connected to an input of a latch circuit (not illustrated) provided in the photo coupler defect detecting circuit 11B-7. The latch circuit generates the defect detecting signal Sd1 related to the defective state of the photo coupler 21 based on the operation result signal Sxor1 input from the XOR gate and outputs the generated defect detecting signal Sd1 to the warning output circuit 12.

### [Operation of Control Circuit]

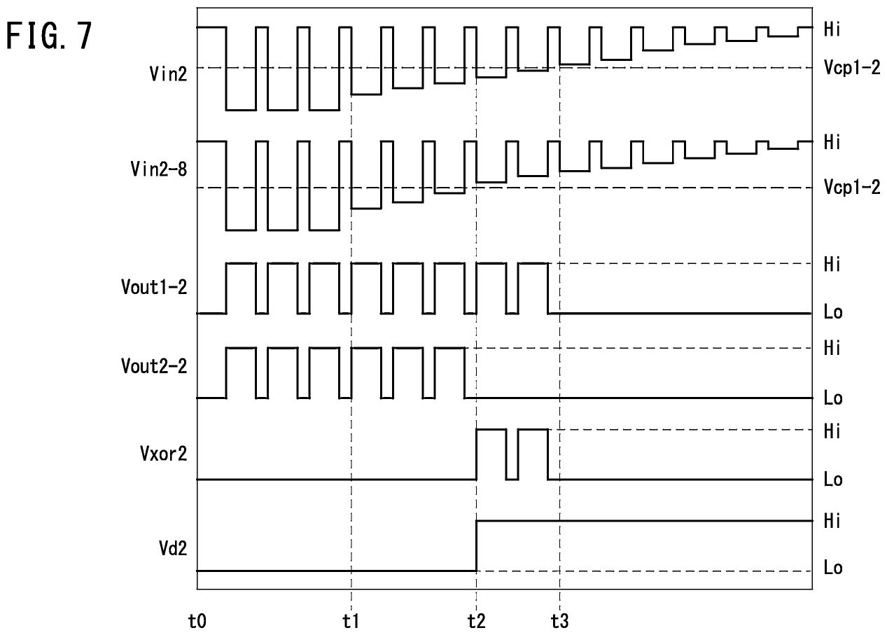

The operation of the control circuit 1B according to the present embodiment will be described with reference to FIG. 7 as well as FIGS. 5, 6. In the control circuit 1B, the detection operation to detect the defective state of the photo coupler 21 in the high-side control IC 7B is the same as the detection operation to detect the defective state of the photo coupler 22 in the low-side control IC 8B. On this account, the following describes the operation of the control circuit 1B by taking, as an example, the detection operation to detect the defective state of the photo coupler 22 in the low-side control IC 8B, that is, the detection operation to detect the defective state of the photo coupler 22 by the control circuit 1B.

FIG. 7 is a timing chart schematically illustrating an example of the operation waveform of the control circuit 1B in a case where the defective state of the photo coupler 22 due to long-term deterioration is detected. The first row in FIG. 7 indicates respective voltage waveforms of the voltage Vin2 of the first input signal Sin2 and the voltage Vcp1-2 of the first compare signal Scp1-2, input into the first comparator 131-8. The second row in FIG. 7 indicates respective voltage waveforms of the voltage Vin2-8 of the second input signal Sin2-8 and the voltage Vcp1-2 of the first compare signal Scp1-2, input into the second comparator 111-8. The third row in FIG. 7 indicates the voltage waveform of the voltage Vout1-2 of the first output signal Sout1-2. The fourth row in FIG. 7 indicates the voltage waveform of the voltage Vout2-2 of the second output signal Sout2-2. The fifth row in FIG. 7 indicates the voltage waveform of the voltage Vxor2 of the operation result signal Sxor2. The sixth row in FIG. 7 indicates the voltage waveform of the voltage Vd2 of the defect detecting signal Sd2. The operating time of the photo coupler 22 is illustrated on the horizontal axis in the graph illustrated in FIG. 7, and respective voltages of the first to sixth rows are illustrated on the vertical axis in the graph illustrated FIG. 7. In the graph illustrated in FIG. 7, time elapses from the left to the right. Note that, when an accumulated operation period reaches several years, the photo coupler 22 starts to deteriorate, but, in FIG. 7, in order to facilitate understanding, the time axis on the horizontal axis ignores the accumulated operation period required for deterioration of the photo coupler 22.

In FIG. 7, a period during which the voltage levels of the voltages Vin2, Vin2-8 are at the high level Hi is a period during which the control device 3 (see FIG. 5) is to control the IGBT 61 (see FIG. 5) to the OFF state. In the meantime, a period during which the voltage levels of the voltages Vin2, Vin2-8 are not at the high level Hi is a period during which the control device 3 is to control the IGBT 61 to the ON state. In the description of the present embodiment, for convenience of this description, the “period during which the voltage levels of the voltages Vin2, Vin2-8 are at the high level Hi” is referred to as a “high-level period,” and the “period during which the voltage levels of the voltages Vin2, Vin2-8 are not at the high level Hi” is referred to as a “low-level period.”

Similarly to the control circuit 1A according to the first embodiment, in the control circuit 1B during the high-level period, a current output from the constant current source 141-8 flows through the resistance elements 142-8, 143-8 without flowing through the photo coupler 22 side, and a current output from the constant current source 151-8 flows through the resistance elements 152-8, 153-8 without flowing through the photo coupler 22 side. As described above, the constant current source 141-8 and the constant current source 151-8 have an equivalent current output capability, and the combined resistance of the resistance elements 142-8, 143-8 is set to generally the same resistance value as the combined resistance of the resistance elements 152-8, 153-8. Accordingly, in the high-level period, the current amount of the current flowing from the constant current source 141-8 to the resistance elements 142-8, 143-8 is generally the same as the current amount of the current flowing from the constant current source 151-8 to the resistance elements 152-8, 153-8. In the meantime, the resistance element 143-8 is set to a resistance value lower than the resistance element 153-8.

Accordingly, as illustrated in FIG. 7, in the high-level period, the potential difference between the voltage Vin2 and the voltage Vcp1-2 of the first compare signal Scp1-2 is smaller than the potential difference between the voltage Vin2-8 and the voltage Vcp1-2. Further, regardless of whether or not the photo coupler 22 deteriorates, respective currents output from the constant current source 141-8 and the constant current source 151-8 hardly flow through the photo coupler 22 side in the high-level period. Accordingly, in the high-level period, the potential difference between the voltage Vin2 and the voltage Vcp1-2 of the first compare signal Scp1-2 is generally constant, and the potential difference between the voltage Vin2-8 and the voltage Vcp1-2 is also generally constant.

The current amount flowing from the constant current source 141-8 to the resistance element 143-8 is smaller in the low-level period than in the high-level period, and the current amount flowing from the constant current source 151-8 to the resistance element 153-8 is also smaller in the low-level period than in the high-level period. However, similarly to the high-level period, in the low-level period, the current amount flowing from the constant current source 141-8 to the resistance element 143-8 is generally the same as the current amount flowing from the constant current source 151-8 to the resistance element 153-8. On this account, in the low-level period, a voltage drop caused in the resistance element 153-8 due to the current flowing therethrough from the constant current source 151-8 is larger than a voltage drop caused in the resistance element 143-8 due to the current flowing therethrough from the constant current source 141-8. Accordingly, as illustrated in FIG. 7, in the low-level period, the voltage Vin2-8 of the second input signal Sin2-8 becomes higher than the voltage Vcp1-2 of the first compare signal Scp1-2 at a stage earlier than the voltage Vin2 of the first input signal Sin2.

In the example of the operation waveform of the control circuit 1B as illustrated in FIG. 7, the photo coupler 22 starts to deteriorate at time t1. Further, in the example of the operation waveform, at time t2 when the deterioration of the photo coupler 22 progresses more than at time t1, the voltage Vin2-8 of the second input signal Sin2-8 becomes higher than the voltage Vcp1-2 of the first compare signal Scp1-2 earlier than the voltage Vin2 of the first input signal Sin2. Further, in the example of the operation waveform, at time t3 when the deterioration of the photo coupler 22 progresses more than at time t2, the voltage Vin2 of the first input signal Sin2 becomes higher than the voltage Vcp1-2 of the first compare signal Scp1-2.

Accordingly, similarly to the photo coupler defect detecting circuit 11A-8 (see FIG. 2) in the first embodiment, in a period from time t0 to time t2, the photo coupler defect detecting circuit 11B-8 (see FIG. 6) provided in the control circuit 1B outputs, to the warning output circuit 12 (see FIG. 6), the operation result signal Sxor2 having the voltage Vxor2 the voltage level of which is at the low level Lo, and the defect detecting signal Sd2 having the voltage Vd2 the voltage level of which is at the low level Lo. Hereby, the warning output circuit 12 does not output the alarm signal Sarm to the control device 3.

Further, similarly to the photo coupler defect detecting circuit 11A-8, in a period from time t2 to time t3, the photo coupler defect detecting circuit 11B-8 outputs, to the warning output circuit 12, the operation result signal Sxor2 having the voltage Vxor2 the voltage level of which is at the high level Hi, and the defect detecting signal Sd2 having the voltage Vd2 the voltage level of which is at the high level Hi. Hereby, the warning output circuit 12 outputs, to the control device 3, the alarm signal Sarm indicating that the state of the photo coupler 22 is at the deterioration alarm level.

Further, similarly to the photo coupler defect detecting circuit 11A-8, in a period after time t3, the photo coupler defect detecting circuit 11B-8 outputs, to the warning output circuit 12, the operation result signal Sxor2 having the voltage Vxor2 the voltage level of which is at the low level Lo, and the defect detecting signal Sd2 having the voltage Vd2 the voltage level of which is at the high level Hi. Hereby, the warning output circuit 12 outputs, to the control device 3, the alarm signal Sarm indicating that the photo coupler 22 is in the deteriorated state.

The photo coupler defect detecting circuit 11B-8 outputs, to the warning output circuit 12, the operation result signal Sxor2 and the defect detecting signal Sd2 generated from the operation result signal Sxor2. The operation result signal Sxor2 is a signal obtained by performing an exclusive-OR operation on the signal level of the first output signal Sout1-2 and the signal level of the second output signal Sout2-2. On this account, the defect detecting signal Sd2 is a signal based on the first output signal Sout1-2 and the second output signal Sout2-2. Accordingly, the photo coupler defect detecting circuit 11B-8 detects the defective state of the photo coupler 22 based on the first output signal Sout1-2 output from the first comparator 131-8 and the second output signal Sout2-2 output from the second comparator 111-8.

The first output signal Sout1-2 is a comparison result signal obtained by the first comparator 131-8 comparing the first input signal Sin2 with the first compare signal Scp1-2. That is, the first output signal Sout1-2 is a signal based on the first input signal Sin2. Accordingly, the photo coupler defect detecting circuit 11B-8 detects the defective state of the photo coupler 22 based on the first input signal Sin2 and the first output signal Sout1-2 output from the first determination circuit 13-8.

Similarly to the photo coupler detecting circuit 11A-8 in the first embodiment, at the time of detection of the deterioration of the photo coupler 22, the photo coupler defect detecting circuit 11B-8 can detect the defective state of the photo coupler 22 while the IGBT 61 controlled based on the control signal Sic2 input from the photo coupler 22 via the low-side input terminal Tin2 performs the switching operation.

For example, the period from time t2 to time t3 in FIG. 7 is a period during which the voltage level of the voltage Vout1-2 of the first output signal Sout1-2 is repeatedly changed between the high level Hi and the low level Lo in response to the signal level of the control signal Sic2. The gate drive circuit 81 generates a gate drive signal for causing the IGBT 61 to perform the switching operation by use of the first output signal Sout1-2 input from the first comparator 131-8. Accordingly, in this period, the gate drive circuit 81 can drive the IGBT 61 by the switching operation based on changes in the signal level of the control signal Sic2. In the meantime, in the period from time t2 to time t3, the photo coupler defect detecting circuit 11B-8 outputs, to the warning output circuit 12, the operation result signal Sxor2 the signal level of which is at the high level Hi and the defect detecting signal Sd2 the signal level of which is at the high level Hi, so that it is possible to detect the state of the photo coupler 22 being at the deterioration alarm level.

Even in a period during which the IGBT 61 does not perform the switching operation after the defective state of the photo coupler 22 is detected (that is, a period after time t3 illustrated in FIG. 7), the photo coupler defect detecting circuit 11B-8 can detect the photo coupler 22 being in the deteriorated state. That is, in a period during which the IGBT 61 does not perform the switching operation after the defective state of the photo coupler 22 is detected, the photo coupler defect detecting circuit 11B-8 outputs, to the warning output circuit 12, the operation result signal Sxor2 the signal level of which is at the low level Lo and the defect detecting signal Sd2 the signal level of which is at the high level Hi, so that it is possible to detect the photo coupler 22 being in the deteriorated state.

As described above, the control circuit 1B according to the present embodiment includes the photo coupler defect detecting circuit 11B-7, 11B-8 configured to detect a defective state including deterioration and abnormality of the photo coupler 21, 22, and the warning output circuit 12 configured to notify that the defective state of the photo coupler 21, 22 is detected by the photo coupler defect detecting circuit 11B-7, 11B-8.

Further, the semiconductor module SMB according to the present embodiment includes the control circuit 1B according to the present embodiment, the IGBT 51 controlled based on the control signal Sic1, and the IGBT 61 controlled based on the control signal Sic2.

With the control circuit 1B and the semiconductor module SMB having such a configuration, it is possible to control detection of a defective state caused due to the life of the photo coupler 21, 22.

The present invention is not limited to the first embodiment and the second embodiment, and various modifications can be made.

In the first embodiment and the second embodiment, a “first input signal based on a control signal” is the first input signal Sin1, Sin2 generated by the signal generating circuit 14-7, 14-8 based on the control signal Sic1, Sic2, but the present invention is not limited to this. For example, the “first input signal based on a control signal” may be a control signal itself input from the photo coupler side.

In the first embodiment, the first output signal Sout1-1, Sout1-2 used for both detection of the defective state of the photo coupler 21, 22 and generation of the gate drive signal to drive the IGBT 51, 61 is set to be higher than the second output signal Sout2-2 used only for detection of the defective state of the photo coupler 21, 22. However, the present invention is not limited to this. The high-low relationship between the first output signal Sout1-1, Sout1-2 and the second output signal Sout2-2 is set in accordance with the logic of the control circuit 1A, 1B and the semiconductor module SMA, SMB as appropriate, provided that the first output signal Sout1-1, Sout1-2 and the second output signal Sout2-2 have different signal levels.

The first embodiment and the second embodiment have described, as an example, the photo coupler externally attached to the outside of the semiconductor module as an optical coupler, but the present invention is not limited to this. Even when the optical coupler is provided inside the semiconductor module, for example, an effect similar to the control circuit and the semiconductor module according to the first embodiment and the second embodiment can be obtained.

The first embodiment and the second embodiment have described, as an example, the photo coupler, but the present invention is not limited to this. The control circuit and the semiconductor module according to the present invention can detect a defective state including deterioration and abnormality even in an active element such as a transistor, a diode and the like, and a passive element such as a resistance element, an inductor, a capacitor and the like, for example. For example, the control circuit and the semiconductor module according to the present invention can detect a short defect or an open defect caused in the active element or the passive element based on changes in a voltage applied between both terminals of the active element and the passive element or a current flowing between both the terminals.

The first embodiment and the second embodiment have described detection of the defective state of the optical coupler by taking, as an example, detection of long-term deterioration of the photo coupler, but the present invention is not limited to this. For example, even in a case where an abnormality that is not long-term deterioration is caused in the optical coupler, the control circuit and the semiconductor module according to the present invention can detect the abnormality.

The first embodiment and the second embodiment have described, as an example, a semiconductor module that exercise a function as an inverter for converting a direct-current power into a single-phase alternating-current power, but the present invention is not limited to this. For example, when the control circuit according to the present invention includes a detecting unit corresponding to the photo coupler defect detecting circuit for each switching element provided in each of a plurality of phases obtained by converting a direct-current power, the control circuit can detect the defective state of an optical coupler connected to or provided in a semiconductor module exercising a function as an inverter for converting a direct-current power into alternating-current powers of a plurality of phases.

The technical scope of the present invention is not limited to the exemplary embodiments illustrated and described herein and covers all embodiments that provides effects equivalent to those intended by the present invention. Further, the technical scope of the present invention is not limited to combinations of features of the invention defined by Claims but can be defined by any desired combination of specific features among the features disclosed herein.

### REFERENCE SIGNS LIST

1A, 1B control circuit
3 control device
5, 6 semiconductor element
7A high-side control IC
8A low-side control IC
11A-7, 11A-8, 11B-7, 11B-8 photo coupler defect detecting circuit
12 warning output circuit
13-7, 13-8 first determination circuit
14-7, 14-8, 15-7, 15-8 signal generating circuit
21, 22 photo coupler
31 NOT gate
32, 141-2, 141-3, 142-7, 142-8, 143-7, 143-8, 152-7, 152-8, 153-7, 153-8 resistance element
51, 61 IGBT
52, 62 freewheeling diode
71, 81 gate drive circuit
72, 82, 91, 92 power supply terminal
73, 83 reference potential terminal
93 pull-up resistor
94 constant voltage source
111-8 second comparator
112-8 compare signal generation section
113-8 XOR gate
114-8 latch circuit
131-7, 131-8 first comparator
132-7, 132-8 compare signal generation section
141-7, 141-8, 151-7, 151-8 constant current source
221 light-emitting diode
222 photo diode
223 transistor
7A, 7B high-side control IC
8A, 8B low-side control IC
S1, S2 input signal
Sarm alarm signal
Scp1-2 first compare signal
Scp2-2 second compare signal
Sd1, Sd2 defect detecting signal
Sic1, Sic2 control signal
Sin1, Sin2 first input signal
Sin2-8 second input signal
SMA, SMB semiconductor module
SOH overheating detecting signal
Sout1-1, Sout1-2 first output signal
Sout2-2 second output signal
Sxor1, Sxor2 operation result signal
T31, T32 signal output terminal
T33 signal input terminal
Tarm alarm terminal
Tcom common reference potential terminal
Tgnd1 high-side ground terminal
Tgnd2 low-side ground terminal
Tin1 high-side input terminal
Tin2 low-side input terminal
Tn negative-side power-input terminal
To alternating-current voltage output terminal
Tp positive-side power-input terminal
Tvc1 high-side power supply terminal
Tvc2 low-side power supply terminal

1. A control circuit comprising:
a detecting unit configured to detect a defective state including deterioration and abnormality of an optical coupler; and
a notifier configured to notify that the defective state is detected by the detecting unit.

2. The control circuit according to claim 1, wherein:
the detecting unit is able to detect the defective state while a semiconductor switching element performs a switching operation; and
the notifier is able to notify that the defective state is detected by the detecting unit while the semiconductor switching element performs the switching operation.

3. The control circuit according to claim 2, wherein
in a case where a degree of the defective state detected by the detecting unit is within a predetermined range while the semiconductor switching element performs the switching operation, the notifier notifies that the defective state is detected by the detecting unit while the semiconductor switching element continues the switching operation.

4. The control circuit according to claim 2, further comprising:
a first determination unit configured to determine a signal level of a first input signal based on a control signal to control the semiconductor switching element, wherein
the detecting unit detects the defective state based on the first input signal and a first output signal output from the first determination unit.

5. The control circuit according to claim 4, wherein:
the first determination unit has a first comparator configured to compare the signal level of the first input signal with a signal level of a first compare signal set at a predetermined signal level; and
the detecting unit has a second comparator configured to compare the signal level of the first input signal with a signal level of a second compare signal set at a signal level different from the first compare signal, and detects the defective state based on the first output signal output from the first comparator and a second output signal output from the second comparator.

6. The control circuit according to claim 4, wherein:
the first determination unit has a first comparator configured to compare the signal level of the first input signal with a signal level of a first compare signal set at a predetermined signal level; and
the detecting unit has a second comparator configured to compare a signal level of a second input signal having a single level different from the first input signal and based on the control signal with the signal level of the first compare signal, and detects the defective state based on the first output signal output from the first comparator and a second output signal output from the second comparator.

7. The control circuit according to claim 1, wherein
the optical coupler is a photo coupler.

8. The control circuit according to claim 2, wherein
the optical coupler is a photo coupler.

9. The control circuit according to claim 3, wherein
the optical coupler is a photo coupler.

10. The control circuit according to claim 4, wherein
the optical coupler is a photo coupler.

11. The control circuit according to claim 5, wherein
the optical coupler is a photo coupler.

12. The control circuit according to claim 6, wherein
the optical coupler is a photo coupler.

13. A semiconductor module comprising:
the control circuit according to claim 1; and
a semiconductor switching element controlled based on a control signal.

14. A semiconductor module comprising:
the control circuit according to claim 7; and
a semiconductor switching element controlled based on a control signal.

15. A semiconductor module comprising:
the control circuit according to claim 2; and
the semiconductor switching element.

16. A semiconductor module comprising:
the control circuit according to claim 3; and
the semiconductor switching element.

17. A semiconductor module comprising:
the control circuit according to claim 4; and
the semiconductor switching element.

18. A semiconductor module comprising:
the control circuit according to claim 5; and
the semiconductor switching element.

19. A semiconductor module comprising:
the control circuit according to claim 6; and
the semiconductor switching element.

20. A semiconductor module comprising:
the control circuit according to claim 8; and
the semiconductor switching element.
